(19) United States
(12) Patent Application Publication
(10) Pub. No.: US 2024/0313714 A1
(43) Pub. Date: Sep. 19, 2024

(54) TRACKER MODULE, RADIO FREQUENCY SYSTEM, AND COMMUNICATION DEVICE

(71) Applicant: Murata Manufacturing Co., Ltd., Nagaokakyo-shi (JP)

(72) Inventors: Tatsuya BANNO, Nagaokakyo-shi (JP); Atsushi HIRONO, Nagaokakyo-shi (JP); Kazuto HIRAI, Nagaokakyo-shi (JP)

(21) Appl. No.: 18/598,394

(22) Filed: Mar. 7, 2024

(30) Foreign Application Priority Data
Mar. 16, 2023 (JP) 2023-042413

(51) Int. Cl. H03F 3/195; H01L 23/66; H01L 25/16; H03F 3/24

(52) U.S. Cl. CPC H03F 3/195; H01L 23/66; H01L 25/16; H03F 3/245; H01L 2223/6616; H01L 2223/6677; H03F 2200/451

(57) ABSTRACT

A tracker module includes a module laminate, a first IC chip, and a second IC chip. The first IC chip is disposed on the module laminate. The second IC chip is configured to control a power amplifier. The first IC chip includes at least one switch included in a switched-capacitor circuit and at least one switch included in a supply modulator. The switched-capacitor circuit is configured to generate a plurality of discrete voltages based on an input voltage, and the supply modulator is configured to selectively output at least one of the plurality of discrete voltages to the power amplifier. The second IC chip is disposed on the module laminate and coupled to the first IC chip.

### CROSS REFERENCE TO RELATED APPLICATIONS

The present disclosure claims the benefit of priority to Japanese Patent Application No. 2023-042413, filed Mar. 16, 2023, which is incorporated by reference herein in its entirety.

### TECHNICAL FIELD

The present disclosure generally relates to a tracker module, a radio frequency system, and a communication device, such as a tracker module including a plurality of IC chips, a radio frequency system including a tracker module, and a communication device including a radio frequency system.

### BACKGROUND

In a related disclosure, such as U.S. Pat. No. 8,829,993, a power supply control unit is provided. The power supply control unit is capable of supplying a power amplifier with a power supply voltage dynamically regulated in accordance with a radio frequency signal as time passes.

As described in U.S. Pat. No. 8,829,993, when a configuration of a power supply control unit is modularized, a size of the power supply control unit may be increased.

### SUMMARY OF THE INVENTION

Thus, according to the exemplary aspects of the disclosure, a tracker module, a radio frequency system, and a communication device are provided. The tracker module, the radio frequency system, and the communication device can be downsized.

In an exemplary aspect, a tracker module is provided that include a module laminate, a first IC chip, and a second IC chip. The first IC chip is disposed on the module laminate. The second IC chip is configured to control a power amplifier. The first IC chip includes at least one switch included in a switched-capacitor circuit and at least one switch included in a supply modulator. The switched-capacitor circuit is configured to generate a plurality of discrete voltages based on an input voltage, and the supply modulator is configured to selectively output at least one of the plurality of discrete voltages to the power amplifier. The second IC chip is disposed on the module laminate and coupled to the first IC chip.

In an exemplary aspect, the tracker module includes another second module laminate. The other module laminate is separated from the module laminate. The power amplifier is disposed on the other module laminate.

In another exemplary aspect, a radio frequency system is provided that includes the tracker module and the power amplifier. The power amplifier is disposed on the module laminate.

In another exemplary aspect, a communication device is provided that includes the radio frequency system and a signal processing circuit. The signal processing circuit is connected (or coupled) to the radio frequency system.

In yet another exemplary aspect, the tracker module, the radio frequency system, and the communication device can be downsized according to the aspects of the present disclosure.

### BRIEF DESCRIPTION OF DRAWINGS

FIG. 1 is a cross-sectional view of a tracker module, a radio frequency system, and a communication device according to a first exemplary embodiment of the disclosure;

FIG. 2 is a circuit block diagram of a power supply circuit, the radio frequency system, and the communication device according to the first exemplary embodiment;

FIG. 3A is a waveform chart illustrating one example of a transition in a power supply voltage in a digital ET mode;

FIG. 3B is a waveform chart illustrating one example of a transition in the power supply voltage in an analog ET mode;

FIG. 4 is a circuit diagram of the power supply circuit according to the first exemplary embodiment;

FIG. 5 is a circuit configuration diagram of a digital control circuit in the power supply circuit according to the first exemplary embodiment;

FIG. 6 is a bottom view of a module laminate of the tracker module according to the first exemplary embodiment;

FIG. 7 is a cross-sectional view of a tracker module, a radio frequency system, and a communication device according to a second exemplary embodiment of the disclosure;

FIG. 8 is a cross-sectional view of a tracker module according to a third exemplary embodiment of the disclosure;

FIG. 9 is a cross-sectional view of a tracker module according to a fourth exemplary embodiment of the disclosure;

FIG. 10 is a cross-sectional view of an exemplary tracker module, an exemplary radio frequency system, and an exemplary communication device according to a first Reference Example; and

FIG. 11 is a cross-sectional view of an exemplary tracker module according to a second Reference Example.

### DETAILED DESCRIPTION OF EMBODIMENTS

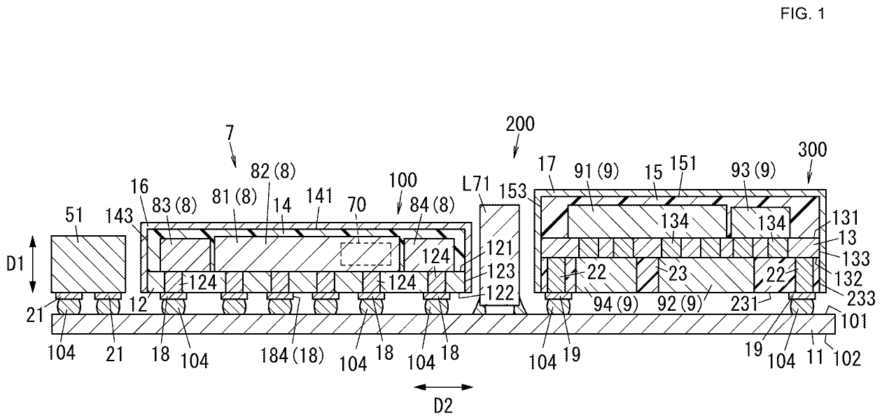

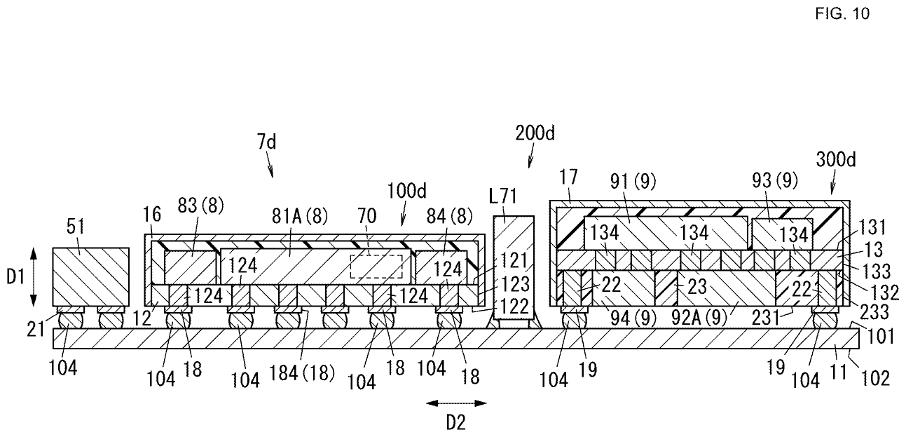

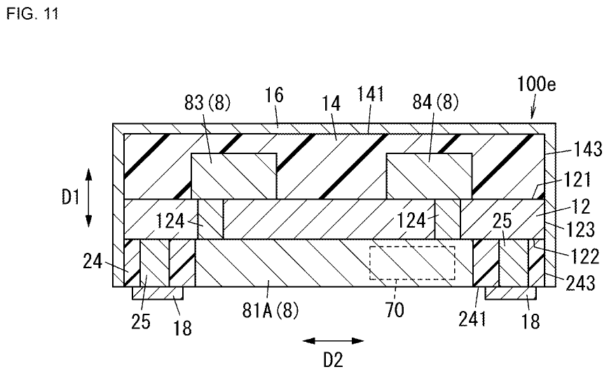

In the disclosure, a description of tracker modules, radio frequency systems, and communication devices can be provided according to first to fourth exemplary embodiments (or Embodiments 1 to 4) with reference to the drawings, such as FIGS. 1-9. Additionally, a description of tracker modules, radio frequency systems, and communication devices according to a first and a second reference examples (or Reference Examples 1 and 2) can be provided with reference to the drawings, such as FIGS. 10-11. Figures to be referred to in the subsequent embodiments or the like are schematic diagrams. Sizes and thicknesses of components in the figures do not necessarily reflect actual dimensions, and ratios of the sizes and the thicknesses among the components also do not necessarily reflect an actual dimensional ratio.

### Embodiment 1

### (1) Tracker Module

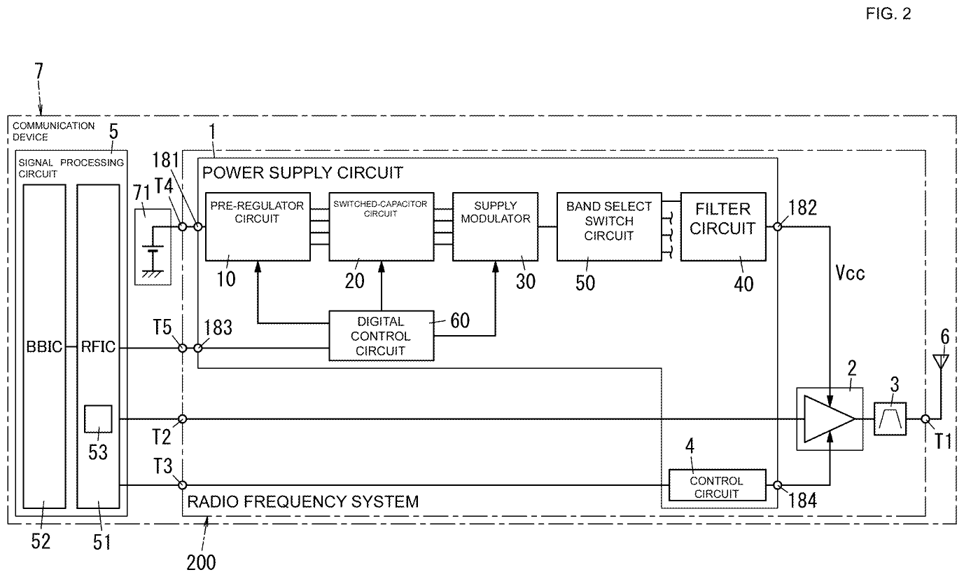

A tracker module 100 can be provided according to a first exemplary embodiment (or Embodiment 1) with reference to FIGS. 1-2.

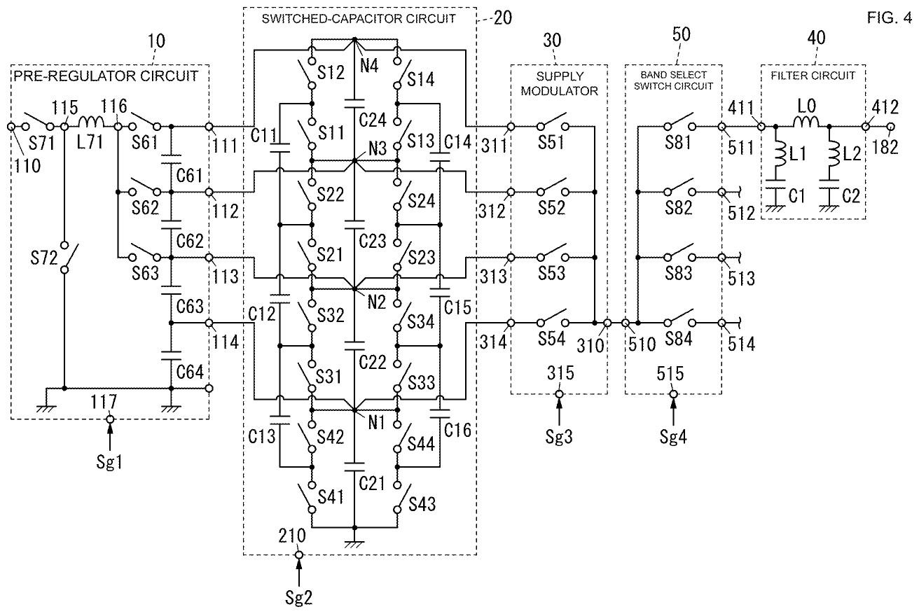

As illustrated in FIGS. 1-2, the tracker module 100 according to the first exemplary embodiment (or Embodiment 1) of the disclosure includes a module laminate 12, a first IC chip 81, and a second IC chip 82. The first IC chip 81 is disposed on the module laminate 12. The second IC chip 82 is configured to control a power amplifier 2. In an example, the first IC chip 81 includes at least one switch from switches S61 to S64, S71, and S72, which are shown in FIG. 4 and included in a pre-regulator circuit 10 and at least one switch from switches S51 to S54, which are shown in FIG. 4 and included in a supply modulator 30. In an example, the first IC chip 81 includes at least one switches from switches S11 to S14, S21 to S24, S31 to S34, and S41 to S44, which are shown in FIG. 4 and included in a switched-capacitor circuit 20. The switched-capacitor circuit 20 is configured to generate a plurality of discrete voltages based on an input voltage, and the supply modulator 30 is configured to selectively output at least one of the plurality of discrete voltages to the power amplifier 2. The second IC chip 82 is disposed on the module laminate 12 where the first IC chip 81 is disposed.

### (2) Circuit Configuration of Power Supply Circuit, Radio Frequency System, and Communication Device

Still referring to FIG. 2, an exemplary circuit configuration of a power supply circuit 1, a radio frequency system 200, and a communication device 7 according to the first exemplary embodiment (or Embodiment 1) of the disclosure can be shown.

### (2.1) Circuit Configuration of Radio Frequency System

As illustrated in FIG. 2, the radio frequency system 200 includes the power supply circuit 1, the power amplifier 2, a filter 3, and a plurality of external connection terminals. The plurality of external connection terminals includes an antenna terminal T1, a signal input terminal T2, a first control terminal T3, a power supply connection terminal T4, and a plurality of second control terminals T5, such as four. It is noted that only one of second control terminals T5 is illustrated in FIG. 2.

Although not illustrated, the radio frequency system 200 may also include a low noise amplifier and a receive path including a receiving filter. That is, the radio frequency system 200 further includes the low noise amplifier, the receiving filter, and an input matching circuit provided between the low noise amplifier and the receiving filter.

According to an exemplary aspect, the power supply circuit 1 is a circuit that supplies the power amplifier 2 with a power supply voltage Vcc having a voltage level selected from a plurality of discrete voltage levels, based on an envelope signal.

In response to the communication device 7 including the power supply circuit 1 and the power amplifier 2, an envelope tracking method (hereinafter referred to as an “ET method”) is used when the power amplifier 2 amplifies a radio frequency signal. ET methods include an analog envelope tracking method (hereinafter referred to as an “analog ET method”) and a digital envelope tracking method (hereinafter referred to as a “digital ET method”).

The digital ET method is a method of tracking an envelope of a radio frequency signal (or a modulated signal) within one frame using a plurality of discrete voltages with different voltage levels. Hereinafter, a mode that applies the digital ET method to generate the power supply voltage Vcc is referred to as a digital ET mode. In addition, the analog ET method is a method of using continuous voltage levels to track an envelope of a radio frequency signal. Hereinafter, a mode that uses the analog ET method to generate the power supply voltage Vcc is referred to as an analog ET mode.

A frame represents a unit that forms a radio frequency signal. For example, in 5G NR (or 5^{th} Generation New Radio) and LTE® (or Long Term Evolution), a frame includes 10 sub-frames, each sub-frame having a plurality of slots, and each slot having a plurality of symbols. Each sub-frame has a length of 1 ms and a frame has a length of 10 ms.

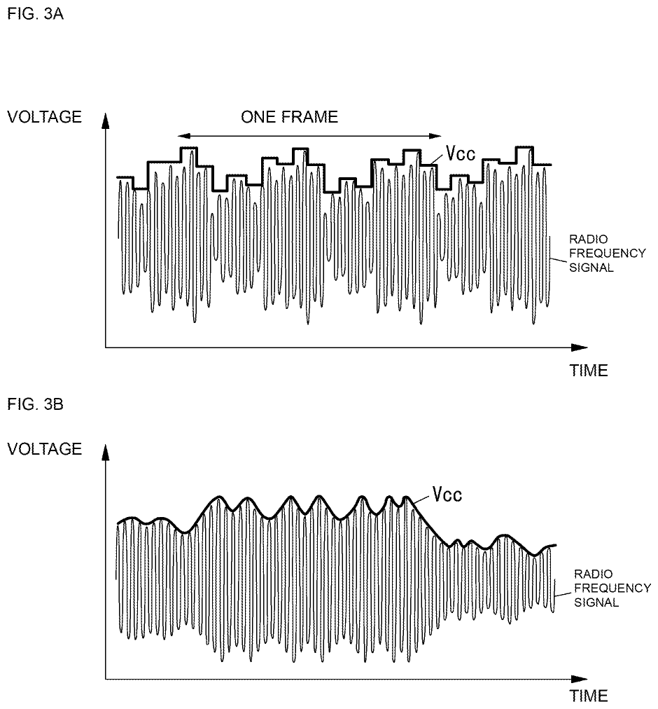

In an exemplary aspect of the disclosure, the digital ET mode and the analog ET mode can be provided with reference to FIG. 3A and FIG. 3B.

In the digital ET mode, as illustrated in FIG. 3A, the envelope of the radio frequency signal is tracked by varying the power supply voltage VCC to the plurality of discrete voltage levels within one frame. As a result, a waveform of the power supply voltage VCC becomes that of a rectangular wave. In the digital ET mode, a power supply voltage level is selected from the plurality of discrete voltage levels based on the envelope signal.

In the analog ET mode, as illustrated in FIG. 3B, the envelope of the radio frequency signal is tracked by continuously varying the power supply voltage Vcc. In the analog ET mode, the power supply voltage Vcc is determined based on the envelope signal. In the analog ET mode, when a channel bandwidth is narrow (e.g., less than 60 MHz), the power supply voltage Vcc easily follows a change in the envelope of the radio frequency signal. However, when the channel bandwidth is wide (e.g., equal to or higher than 60 MHz), the power supply voltage Vcc has difficulty in following the change in the envelope of the radio frequency signal. In other words, when the channel bandwidth is wide, an amplitude change in the power supply voltage Vcc easily lags behind the change in the envelope of the radio frequency signal.

In contrast to this configuration, when the channel bandwidth is wide, application of the digital ET mode can improve followability of the power supply voltage Vcc to the radio frequency signal.

As illustrated in FIG. 2, the power supply circuit 1 includes a pre-regulator circuit 10, the switched-capacitor circuit 20, the supply modulator 30, and a control circuit 4.

The pre-regulator circuit 10 is, for example, a DC (Direct Current)/DC converter that converts a direct current voltage (or a first voltage) supplied from a direct current power source 71 included in the communication device 7 into a second voltage. The pre-regulator circuit 10 is configured to perform a voltage step-up operation that makes a voltage value of the first voltage larger than that of the second voltage, and a voltage step-down operation that makes the voltage value of the second voltage smaller than that of the first voltage. That is, the pre-regulator circuit 10 is a DC/DC converter of a step-up/down type.

The switched-capacitor circuit 20 is configured to set the second voltage from the pre-regulator circuit 10 as an input voltage and generate a plurality of discrete voltages (or a plurality of third voltages). The plurality of discrete voltages has mutually different voltage levels. The switched-capacitor circuit 20 may be referred to as a switched-capacitor voltage balancer.

The supply modulator 30 is configured to selectively output, to the power amplifier 2, at least one of the plurality of discrete voltages (or the plurality of third voltages) generated by the switched-capacitor circuit 20, based on a digital control signal corresponding to the envelope signal. The supply modulator 30 outputs the at least one discrete voltage selected from the plurality of discrete voltages. The power supply circuit 1 can change the voltage level of an output voltage (e.g., the power supply voltage Vcc) of the supply modulator 30 as time passes, by repeating the selection of the discrete voltage in the supply modulator 30 over time. This allows the power supply circuit 1 to change the voltage level of the power supply voltage Vcc to be supplied to the power amplifier 2, as time passes.

In an exemplary aspect, the control circuit 4 is connected to an RF signal processing circuit 51 of the signal processing circuit 5 with the first control terminal T3 interposed therebetween. The control circuit 4 is also connected to a control terminal of the power amplifier 2 with a control terminal 184, to be described below, interposed therebetween. By receiving a control signal from the RF signal processing circuit 51 of the signal processing circuit 5, the control circuit 4 controls a size of a bias current (or a bias voltage) to be supplied to the control terminal of the power amplifier 2 and supply timing.

The power amplifier 2 includes an input terminal, an output terminal, a power supply terminal, and a control terminal. The input terminal of the power amplifier 2 is connected to the signal processing circuit 5 of the communication device 7 with the signal input terminal T2 interposed therebetween. The output terminal of the power amplifier 2 is connected to an antenna 6 of the communication device 7 with the filter 3 and the antenna terminal T1 interposed therebetween. The power amplifier 2 amplifies and outputs a radio frequency transmission signal (hereinafter referred to as a “transmission signal”) of a predetermined band outputted from the signal processing circuit 5.

The filter 3 is connected between the output terminal of the power amplifier 2 and the antenna terminal T1. The filter 3 has a pass band including a frequency band of a predetermined band. This allows the filter 3 to cause the transmission signal of the predetermined band amplified by the power amplifier 2 to pass. In the radio frequency system 200, transmission signals outputted from the power amplifier 2 are outputted to the antenna 6 with the filter 3 and the antenna terminal T1 interposed therebetween.

### (2.2) Communication Device

As illustrated in FIG. 2, the communication device 7 includes the radio frequency system 200, the signal processing circuit 5, the antenna 6, and the direct current power source 71. The signal processing circuit 5 is connected to the radio frequency system 200.

The direct current power source 71 is, for example, a rechargeable battery. It is noted that the direct current power source 71 is not limited to a rechargeable battery and may be another battery.

The antenna 6 transmits a transmission signal of a predetermined band outputted from the antenna terminal T1.

The signal processing circuit 5 includes the RF signal processing circuit 51 and a baseband signal processing circuit 52. The RF signal processing circuit 51 is, for example, an RFIC (Radio Frequency Integrated Circuit) and performs signal processing on radio frequency signals. The RF signal processing circuit 51 performs, for example, signal processing such as up-conversion or the like on a radio frequency signal (or transmission signal) outputted from the baseband signal processing circuit 52, and outputs the radio frequency signal subjected to the signal processing. The baseband signal processing circuit 52 is, for example, a BBIC (Baseband Integrated Circuit). The baseband signal processing circuit 52 generates an I-phase signal and a Q-phase signal from a baseband signal. A baseband signal is, for example, an audio signal or an image signal inputted from outside. The baseband signal processing circuit 52 performs IQ modulation processing by synthesizing the I-phase signal and the Q-phase signal, and outputs a transmission signal. Accordingly, the transmission signal is generated as a modulation signal (e.g., an IQ signal) resulting from amplitude modulation of a carrier signal of a predetermined frequency for a period longer than that of the carrier signal.

In addition, the RF signal processing circuit 51 includes a control unit 53 that controls the power supply circuit 1 and the power amplifier 2. The control unit 53 of the RF signal processing circuit 51 causes the supply modulator 30 to select a voltage level of the power supply voltage Vcc used in the power amplifier 2, from the voltage levels of the plurality of discrete voltages generated in the switched-capacitor circuit 20, based on the envelope signal of a radio frequency input signal inputted from the baseband signal processing circuit 52. This allows the power supply circuit 1 to output the power supply voltage Vcc based on the digital envelope tracking. The envelope signal is a signal representing an envelope of a radio frequency signal (e.g., a modulated signal). An envelope value is, for example, (I²+Q²)^{1/2}. Here, (I, Q) represents a constellation point. A constellation point is a point on a constellation diagram representing a signal modulated through digital modulation. (I, Q) is determined by the baseband signal processing circuit 52 based on transmission information, for example. Note that some or all of functions of the RF signal processing circuit 51 as the control unit 53 may be external to the RF signal processing circuit 51. For example, the baseband signal processing circuit 52 or the power supply circuit 1 may include some or all of the functions of the RF signal processing circuit 51 as the control unit 53. For example, the RF signal processing circuit 51 does not include a control function of causing the supply modulator 30 to select the voltage level of the power supply voltage Vcc, and instead, the power supply circuit 1 may include the control function.

### (2.3) Power Supply Circuit

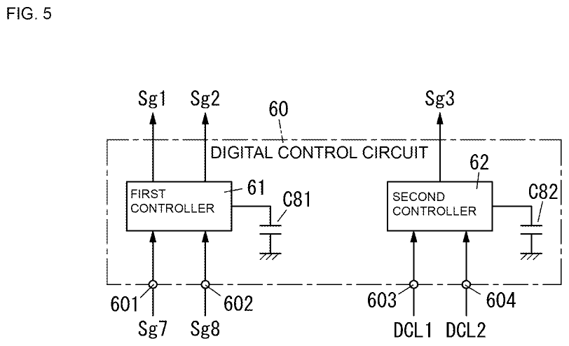

As illustrated in FIG. 4, the power supply circuit 1 includes the pre-regulator circuit 10, the switched-capacitor circuit 20, the supply modulator 30, a filter circuit 40, a band select switch circuit 50, a digital control circuit (e.g., the digital control circuitry 60 in FIG. 5), and a control circuit (e.g., the control circuit 4 in FIG. 2).

### (2.4) Pre-Regulator Circuit

As illustrated in FIG. 4, the pre-regulator circuit 10 includes an input terminal 110, a plurality of (e.g., four in the example of FIG. 4) output terminals 111 to 114, a plurality of inductor connection terminals 115, 116, a control terminal 117, a plurality of (e.g., five in the example of FIG. 4) the switches S61 to S63, S71, and S72, a power inductor L71, and a plurality of (e.g., four in the example of FIG. 4) capacitors C61 to C64. The power inductor L71 is an inductor used to step up and/or step down (e.g., step-up, step-down, or step-up/down) a direct current voltage.

The input terminal 110 is an input terminal for a direct current voltage. That is, the input terminal 110 is a terminal for receiving an input voltage from the direct current power source 71. An exemplary direct current power source 71 can be shown in FIG. 2.

The output terminal 111 is an output terminal of voltage V4. That is, the output terminal 111 is a terminal for supplying the voltage V4 to the switched-capacitor circuit 20. The output terminal 111 is connected to a node N4 of the switched-capacitor circuit 20.

The output terminal 112 is an output terminal of voltage V3. That is, the output terminal 112 is a terminal for supplying the voltage V3 to the switched-capacitor circuit 20. The output terminal 112 is connected to a node N3 of the switched-capacitor circuit 20.

The output terminal 113 is an output terminal of voltage V2. That is, the output terminal 113 is a terminal for supplying the voltage V2 to the switched-capacitor circuit 20. The output terminal 113 is connected to a node N2 of the switched-capacitor circuit 20.

The output terminal 114 is an output terminal of voltage V1. That is, the output terminal 114 is a terminal for supplying the voltage V1 to the switched-capacitor circuit 20. The output terminal 114 is connected to a node N1 of the switched-capacitor circuit 20.

The inductor connection terminal 115 is connected to one end (e.g., first end) of the power inductor L71. The inductor connection terminal 116 is connected to another end (e.g., second end) of the power inductor L71.

The control terminal 117 is an input terminal for a control signal Sg1. That is, the control terminal 117 is a terminal for receiving the control signal Sg1 to control the pre-regulator circuit 10. The control signal Sg1 is a signal for controlling ON/OFF of the plurality of switches S61 to S63, S71, and S72 included in the pre-regulator circuit 10.

The switch S71 is connected between the input terminal 110 and the one end of the power inductor L71. In an example, the switch S71 includes a first terminal connected to the input terminal 110, and a second terminal connected to the one end of the power inductor L71 with the inductor connection terminal 115 interposed therebetween. In a connection configuration described above, by switching ON/OFF, the switch S71 switches connection and disconnection between the input terminal 110 and the one end of the power inductor L71.

The switch S72 is connected between the one end of the power inductor L71 and ground. In an example, the switch S72 includes a first terminal connected to the one end of the power inductor L71 with the inductor connection terminal 115 interposed therebetween, and a second terminal connected to the ground. In the connection configuration described above, by switching ON/OFF, the switch S72 switches connection and disconnection between the one end of the power inductor L71 and the ground.

The switch S61 is connected between the other end of the power inductor L71 and the output terminal 111. In an example, the switch S61 includes a first terminal connected to the other end of the power inductor L71, and a second terminal connected to the output terminal 111. In the connection configuration described above, by switching ON/OFF, the switch S61 switches connection and disconnection between the other end of the power inductor L71 and the output terminal 111.

The switch S62 is connected between the other end of the power inductor L71 and the output terminal 112. In an example, the switch S62 includes the first terminal connected to the other end of the power inductor L71, and a second terminal connected to the output terminal 112. In the connection configuration described above, by switching ON/OFF, the switch S62 switches connection and disconnection between the other end of the power inductor L71 and the output terminal 112.

The switch S63 is connected between the other end of the power inductor L71 and the output terminal 113. In an example, the switch S63 includes a first terminal connected to the other end of the power inductor L71, and a second terminal connected to the output terminal 113. In the connection configuration described above, by switching ON/OFF, the switch S63 switches connection and disconnection between the other end of the power inductor L71 and the output terminal 113.

The capacitor C61 is connected between the output terminal 111 and the output terminal 112. One of two electrodes of the capacitor C61 is connected to the switch S61 and the output terminal 111, and another electrode of the two electrodes of the capacitor C61 is connected to the switch S62 and the output terminal 112 as well as one of two electrodes of the capacitor C62.

In an exemplary aspect, the capacitor C62 is connected (or coupled) between the output terminal 112 and the output terminal 113. The one of the two electrodes of the capacitor C62 is connected to the switch S62 and the output terminal 112 as well as the other of the two electrodes of the capacitor C61, and another electrode of the two electrodes of the capacitor C62 is connected to the switch S63 and the output terminal 113 as well as one of two electrodes of the capacitor C63.

The capacitor C63 is connected between the output terminal 113 and the output terminal 114. The one of the two electrodes of the capacitor C63 is connected to the switch S63 and the output terminal 113 as well as the other of the two electrodes of the capacitor C62, and another electrode of the two electrodes of the capacitor C63 is connected to the output terminal 114 and one of two electrodes of the capacitor C64.

The capacitor C64 is connected between the output terminal 114 and the ground. The one of the two electrodes of the capacitor C64 is connected to the output terminal 114 and the other of the two electrodes of the capacitor C63, and another electrode of the two electrodes of the capacitor C64 is connected to the ground.

The plurality of switches S61 to S63 are controlled so as to be exclusively turned ON. Accordingly, when any of the switches S61 to S63 is turned ON, remaining switches of the switches S61 to S63 are turned OFF. Depending on which of the switches S61 to S63 is turned ON, it is possible to change the voltage levels of the voltages V1 to V4.

The pre-regulator circuit 10 configured as described above supplies the switched-capacitor circuit 20 with electric charges via at least one of the plurality of output terminals 111 to 114.

### (2.5) Switched-Capacitor Circuit

As illustrated in FIG. 4, the switched-capacitor circuit 20 includes a plurality of (e.g., six in the example of FIG. 4) capacitors C11 to C16, a plurality of (e.g., four in the example of FIG. 4) capacitors C21 to C24, a plurality of (e.g., sixteen in the example of FIG. 4) switches S11 to S14, S21 to S24, S31 to S34, S41 to S44, and a control terminal 210.

The control terminal 210 is an input terminal for a control signal Sg2 from the digital control circuit 60, which can be shown in FIG. 5. The control signal Sg2 is a signal for controlling ON/OFF of the plurality of switches S11 to S14, S21 to S24, S31 to S34, and S41 to S44 included in the switched-capacitor circuit 20.

Each of the plurality of capacitors C11 to C16 functions as a flying capacitor (or transfer capacitor). That is, each of the plurality of capacitors C11 to C16 is used to step up or step down the voltage (e.g., input voltage) supplied from the pre-regulator circuit 10. In an example, the plurality of capacitors C11 to C16 moves the electric charges between the capacitors C11 to C16 and the nodes N1 to N4, so that in the four nodes N1 to N4, the voltages V1 to V4 (or voltages to a ground potential) which satisfy V1:V2:V3:V4=1:2:3:4 are maintained. The plurality of voltages V1 to V4 corresponds to a plurality of discrete voltages, each having a plurality of discrete voltage levels. The voltage V1 is a voltage in the node N1, the voltage V2 is a voltage in the node N2, the voltage V3 is a voltage in the node N3, and the voltage V4 is a voltage in the node N4.

The capacitor C11 has two electrodes. One of the two electrodes of the capacitor C11 is connected to one end (e.g., first end) of the switch S11 and one end (e.g., first end) of the switch S12. Another electrode of the two electrodes of the capacitor C11 is connected to one end (e.g., first end) of the switch S21 and one end (e.g., first end) of the switch S22.

The capacitor C12 has two electrodes. One of the two electrodes of the capacitor C12 is connected to one end of the switch S21 and one end of the switch S22. Another electrode of the two electrodes of the capacitor C12 is connected to one end (e.g., first end) of the switch S31 and one end (e.g., first end) of the switch S32.

The capacitor C13 has two electrodes. One of the two electrodes of the capacitor C13 is connected to one end of the switch S31 and one end of the switch S32. Another electrode of the two electrodes of the capacitor C13 is connected to one end (e.g., first end) of the switch S41 and one end (e.g., first end) of the switch S42.

The capacitor C14 has two electrodes. One of the two electrodes of the capacitor C14 is connected to one end (e.g., first end) of the switch S13 and one end (e.g., first end) of the switch S14. Another electrode of the two electrodes of the capacitor C14 is connected to one end (e.g., first end) of the switch S23 and one end (e.g., first end) of the switch S24.

The capacitor C15 has two electrodes. One of the two electrodes of the capacitor C15 is connected to one end of the switch S23 and one end of the switch S24. Another electrode of the two electrodes of the capacitor C15 is connected to one end (e.g., first end) of the switch S33 and one end (e.g., first end) of the switch S34.

The capacitor C16 has two electrodes. One of the two electrodes of the capacitor C16 is connected to one end of the switch S33 and one end of the switch S34. Another electrode of the two electrodes of the capacitor C16 is connected to one end (e.g., first end) of the switch S43 and one end (e.g., first end) of the switch S44.

By a first phase and a second phase being repeated, each of a set of the capacitors C11 and C14, a set of the capacitors C12 and C15, and a set of the capacitors C13 and C16 can perform charging and discharging in a complementary manner.

In an exemplary aspect, in the first phase, the switches S12, S13, S22, S23, S32, S33, S42, and S43 are turned ON. As a result, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

In an exemplary aspect, in the second phase, the switches S11, S14, S21, S24, S31, S34, S41, and S44 are turned ON. As a result, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

By the first phase and the second phase being repeated, for example, the other of the capacitors C12 and C15 can perform discharging in a capacitor C23, while the one of the capacitors C12 and C15 is being charged from the node N2. That is, the capacitors C12 and C15 can perform charging and discharging in a complementary manner. The capacitors C12 and C15 are a pair of flying capacitors that perform charging and discharging in a complementary manner.

It is noted that as with the set of the capacitors C12 and C15, by appropriately changing over the switches, the set of the capacitors C11 and C14 also becomes a pair of the flying capacitors that perform charging from the node and discharging to a smoothing capacitor in a complementary manner. Furthermore, as with the set of the capacitors C12 and C15, by appropriately changing over the switches, the set of the capacitors C13 and C16 also becomes a pair of the flying capacitors that perform charging from the node and discharging to the smoothing capacitor in a complementary manner.

Each of the plurality of capacitors C21 to C24 functions as the smoothing capacitor. That is, each of the capacitors C21 to C24 is used to hold and smooth the voltages V1 to V4 in the nodes N1 to N4.

The capacitor C21 is connected between the node N1 and ground. In an example, the one of the two electrodes of the capacitor C21 is connected to the node N1. On the other hand, the other of the two electrodes of the capacitor C21 is connected to the ground.

The capacitor C22 is connected between the node N2 and the node N1. In an example, the one of the two electrodes of the capacitor C22 is connected to the node N2. On the other hand, the other of the two electrodes of the capacitor C22 is connected to the node N1.

The capacitor C23 is connected between the node N3 and the node N2. In an example, the one of the two electrodes of the capacitor C23 is connected to the node N3. On the other hand, the other of the two electrodes of the capacitor C23 is connected to the node N2.

The capacitor C24 is connected between the node N4 and the node N3. In an example, the one of the two electrodes of the capacitor C24 is connected to the node N4. On the other hand, the other of the two electrodes of the capacitor C24 is connected to the node N3.

The switch S11 is connected between the one of the two electrodes of the capacitor C11 and the node N3. In an example, the one end (e.g., first end) of the switch S11 is the one of the two electrodes of the capacitor C11. On the other hand, another end of the switch S11 (e.g., second end) is connected to the node N3.

The switch S12 is connected between the one of the two electrodes of the capacitor C11 and the node N4. In an example, the one end of the switch S12 (e.g., first end) is connected to the one of the two electrodes of the capacitor C11. On the other hand, another end (e.g., second end) of the switch S12 is connected to the node N4.

The switch S21 is connected between the one of the two electrodes of the capacitor C12 and the node N2. In an example, the one end of the switch S21 (e.g., first end) is connected to the one of the two electrodes of the capacitor C12 and the other of the two electrodes of the capacitor C11. On the other hand, another end (e.g., second end) of the switch S21 is connected to the node N2.

The switch S22 is connected between the one of the two electrodes of the capacitor C12 and the node N3. In an example, the one end of the switch S22 (e.g., first end) is connected to the one of the two electrodes of the capacitor C12 and the other of the two electrodes of the capacitor C11. On the other hand, another end (e.g., second end) of the switch S22 is connected to the node N3. That is, the other end of the switch S22 is connected to the other end of the switch S21.

The switch S31 is connected between the other of the two electrodes of the capacitor C12 and the node N1. In an example, the one end of the switch S31 (e.g., first end) is connected to the other of the two electrodes of the capacitor C12 and the one of the two electrodes of the capacitor C13. On the other hand, another end (e.g., second end) of the switch S31 is connected to the node N1.

The switch S32 is connected between the other of the two electrodes of the capacitor C12 and the node N2. In an example, the one end of the switch S32 (e.g., first end) is connected to the other of the two electrodes of the capacitor C12 and the one of the two electrodes of the capacitor C13. On the other hand, another end (e.g., second end) of the switch S32 is connected to the node N2. That is, the other end of the switch S32 is connected to the other end of the switch S21.

The switch S41 is connected between the other of the two electrodes of the capacitor C13 and the ground. In an example, the one end of the switch S41 (e.g., first end) is connected to the other of the two electrodes of the capacitor C13. On the other hand, another end (e.g., second end) of the switch S41 is connected to the ground.

The switch S42 is connected between the other of the two electrodes of the capacitor C13 and the node N1. In an example, the one end of the switch S42 (e.g., first end) is connected to the other of the two electrodes of the capacitor C13. On the other hand, another end (e.g., second end) of the switch S42 is connected to the node N1. That is, the other end of the switch S42 is connected to the other end of the switch S31.

The switch S13 is connected between the one of the two electrodes of the capacitor C14 and the node N3. In an example, the one end of the switch S13 (e.g., first end) is connected to the one of the two electrodes of the capacitor C14. On the other hand, another end (e.g., second end) of the switch S13 is connected to the node N3. That is, the other end of the switch S13 is connected to the other end of the switch S11 and the other end of the switch S22.

The switch S14 is connected between the one of the two electrodes of the capacitor C14 and the node N4. In an example, the one end of the switch S14 (e.g., first end) is connected to the one of the two electrodes of the capacitor C14. On the other hand, another end (e.g., second end) of the switch S14 is connected to the node N4. That is, the other end of the switch S14 is connected to the other end of the switch S12.

The switch S23 is connected between the one of the two electrodes of the capacitor C15 and the node N2. In an example, the one end of the switch S23 (e.g., first end) is connected to the one of the two electrodes of the capacitor C15 and the other of the two electrodes of the capacitor C14. On the other hand, another end (e.g., second end) of the switch S23 is connected to the node N2. That is, the other end of the switch S23 is connected to the other end of the switch S21 and the other end of the switch S32.

The switch S24 is connected between the one of the two electrodes of the capacitor C15 and the node N3. In an example, the one end of the switch S24 (e.g., first end) is connected to the one of the two electrodes of the capacitor C15 and the other of the two electrodes of the capacitor C14. On the other hand, another end (e.g., second end) of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. In an example, the one end of the switch S33 (e.g., first end) is connected to the other of the two electrodes of the capacitor C15 and the other of the two electrodes of the capacitor C16. On the other hand, another end (e.g., second end) of the switch S33 is connected to the node N1. That is, the other end of the switch S33 is connected to the other end of the switch S31 and the other end of the switch S42.

The switch S34 is connected between the other of the two electrodes of the capacitor C15 and the node N2. In an example, the one end of the switch S34 (e.g., first end) is connected to the other of the two electrodes of the capacitor C15 and the other of the two electrodes of the capacitor C16. On the other hand, another end (e.g., second end) of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. In an example, the one end of the switch S43 (e.g., first end) is connected to the other of the two electrodes of the capacitor C16. On the other hand, another end (e.g., second end) of the switch S43 is connected to the ground.

The switch S44 is connected between the other of the two electrodes of the capacitor C16 and the node N1. In an example, the one end of the switch S44 (e.g., first end) is connected to the other of the two electrodes of the capacitor C16. On the other hand, another end (e.g., second end) of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched between ON and OFF in a complementary manner. In an example, in the first phrase, the first set of switches is turned ON and the second set of switches are turned OFF. Conversely, in the second phase, the first set of switches is turned OFF and the second set of switches is turned ON.

For example, in one of the first phase and the second phase, charging is performed from the capacitors C11 to C13 to the capacitors C21 to C24, and in the other of the first phase and the second phase, charging is performed from the capacitors C14 to C16 to the capacitors C21 to C24. That is, as the capacitors C21 to C24 are always charged from the capacitors C11 to C13 or the capacitors C14 to C16, the nodes N1 to N4 are replenished with electric charges at high speed even when electric currents flow from the nodes N1 to N4 at high speed to the supply modulator 30. This configuration suppresses potential variations in the nodes N1 to N4.

By operating as described above, the switched-capacitor circuit 20 can maintain an approximately equal voltage at both ends of each of the capacitors C21 to C24. In an example, the voltages V1 to V4 that satisfy V1:V2:V3:V4=1:2:3:4 (e.g., voltage to the ground potential) are maintained at the four nodes N1 to N4. The voltage levels of the voltages V1 to V4 correspond to the plurality of discrete voltage levels supplied by the switched-capacitor circuit 20 to the supply modulator 30.

Note that the voltage ratio of V1:V2:V3:V4 is not limited to 1:2:3:4. For example, the voltage ratio of V1:V2:V3:V4 may be 1:2:4:8.

### (2.6) Supply Modulator

As illustrated in FIG. 4, the supply modulator 30 includes a plurality of (e.g., four in the example of FIG. 4) input terminals 311 to 314, a plurality of the (e.g., four in the example of FIG. 4) switches S51 to S54, and an output terminal 310, and a control terminal 315. It is noted that FIG. 4 is merely an example. The supply modulator 30 can include any number of input terminals and any number of switches.

The output terminal 310 is connected to the filter circuit 40. The output terminal 310 is a terminal for supplying, to the power amplifier 2, a voltage selected from the voltages V1 to V4 via the filter circuit 40, as the power supply voltage Vcc.

The plurality of input terminals 311 to 314 is connected to the nodes N4 to N1 of the switched-capacitor circuit 20, respectively. The plurality of input terminals 311 to 314 is each a terminal for receiving the voltages V4 to V1 from the switched-capacitor circuit 20.

The control terminal 315 is an input terminal for a control signal Sg3 from a digital control circuit, such as the digital control circuit 60 shown in FIG. 5. The control signal Sg3 is a signal for controlling ON/OFF of the plurality of switches S51 to S54 included in the supply modulator 30. The supply modulator 30 controls ON/OFF of the plurality of switches S51 to S54 based on the control signal Sg3.

The switch S51 is connected between the input terminal 311 and the output terminal 310. In an example, the switch S51 includes a first terminal connected to the input terminal 311 and a second terminal connected to the output terminal 310. In the connection configuration described above, by switching ON/OFF, the switch S51 switches connection and disconnection between the input terminal 311 and the output terminal 310.

The switch S52 is connected between the input terminal 312 and the output terminal 310. In an example, the switch S52 includes a first terminal connected to the input terminal 312 and the second terminal connected to the output terminal 310. In the connection configuration described above, by switching ON/OFF, the switch S52 switches connection and disconnection between the input terminal 312 and the output terminal 310.

The switch S53 is connected between the input terminal 313 and the output terminal 310. In an example, the switch S53 includes a first terminal connected to the input terminal 313 and the second terminal connected to the output terminal 310. In the connection configuration described above, by switching ON/OFF, the switch S53 switches connection and disconnection between the input terminal 313 and the output terminal 310.

The switch S54 is connected between the input terminal 314 and the output terminal 310. In an example, the switch S54 includes a first terminal connected to the input terminal 314 and the second terminal connected to the output terminal 310. In the connection configuration described above, by switching ON/OFF, the switch S54 switches connection and disconnection between the input terminal 314 and the output terminal 310.

The plurality of switches S51 to S54 is controlled so as to be exclusively turned ON. Accordingly, when any of the switches S51 to S54 is turned ON, remaining switches of the switches S51 to S54 are turned OFF. This allows the supply modulator 30 to output the one voltage selected from the voltages V1 to V4.

As the supply modulator 30 has the configuration described above, a digital control signal corresponding to an envelope signal is inputted from the control terminal 315. Thus, based on the digital control signal inputted from the control terminal 315, the supply modulator 30 controls ON/OFF of the plurality of switches S51 to S54. As a result, the supply modulator 30 selects at least one of the plurality of voltages V1 to V4 generated in the switched-capacitor circuit 20 and outputs the selected voltage.

There are some cases in which a waveform of an output voltage of the supply modulator 30 is not a rectangular wave that includes only a plurality of discrete voltages. In an example, the waveform of the output voltage of the supply modulator 30 becomes a waveform distorted from a rectangular wave due to occurrence of an overshoot voltage (e.g., a spike-like voltage) during a transition from a discrete voltage at a relatively low voltage level to a discrete voltage at a relatively high voltage level. In addition, the waveform of the output voltage of the supply modulator 30 becomes a waveform distorted from a rectangular wave due to occurrence of an undershoot voltage (e.g., a spike-like voltage) during a transition from a discrete voltage at a relatively high voltage level to a discrete voltage at a relatively low voltage level. Such a distortion of the waveform of the output voltage of the supply modulator 30 as described above causes noise. An amplitude of the spike-like voltage increases as an absolute value of a voltage change rate (e.g., dV/dt) increases.

### (2.7) Band Select Switch Circuit

As illustrated in FIG. 4, the band select switch circuit 50 includes a common terminal 510, a plurality of (e.g., four in the example of FIG. 4) switches S81 to S84, a plurality of (e.g., four in the example of FIG. 4) selection terminals 511 to 514, and a control terminal 515. It is noted that FIG. 4 is merely an example. The band select switch circuit 50 can include any number of switches and any number of selection terminals.

The common terminal 510 of the band select switch circuit 50 is connected to the output terminal 310 of the supply modulator 30. For example, a plurality of power amplifiers corresponding to mutually different communication bands is connected to the plurality of selection terminals 511 to 514, respectively. In the example illustrated in FIG. 4, a power amplifier, such as the power amplifier 2 in FIG. 2, is connected to the one selection terminal 511 of the plurality of selection terminals 511 to 514 with the filter circuit 40 interposed therebetween.

The control terminal 515 is an input terminal for a control signal Sg4. That is, the control terminal 515 is a terminal for receiving the control signal Sg4 that indicates one of a plurality of communication bands. The band select switch circuit 50 controls ON/OFF of the plurality of switches S81 to S84 so that the power amplifier corresponding to the communication band indicated by the control signal Sg4 is connected to the supply modulator 30.

The switch S81 is connected between the common terminal 510 and the selection terminal 511. In an example, the switch S81 includes a first terminal connected to the common terminal 510 and a second terminal connected to the selection terminal 511. In the connection configuration described above, by switching ON/OFF, the switch S81 switches connection and disconnection between the common terminal 510 and the selection terminal 511.

The switch S82 is connected between the common terminal 510 and the selection terminal 512. In an example, the switch S82 includes the first terminal connected to the common terminal 510 and a second terminal connected to the selection terminal 512. In the connection configuration described above, by switching ON/OFF, the switch S82 switches connection and disconnection between the common terminal 510 and the selection terminal 512.

The switch S83 is connected between the common terminal 510 and the selection terminal 513. In an example, the switch S83 includes the first terminal connected to the common terminal 510 and a second terminal connected to the selection terminal 513. In the connection configuration described above, by switching ON/OFF, the switch S83 switches connection and disconnection between the common terminal 510 and the selection terminal 513.

The switch S84 is connected between the common terminal 510 and the selection terminal 514. In an example, the switch S84 includes the first terminal connected to the common terminal 510 and a second terminal connected to the selection terminal 514. In the connection configuration described above, by switching ON/OFF, the switch S84 switches connection and disconnection between the common terminal 510 and the selection terminal 514.

In the example of FIG. 4, the plurality of switches S81 to S84 is controlled so as to be exclusively turned ON. Accordingly, when one of the switches S81 to S84 is turned ON, remaining switches of the switches S81 to S84 are turned OFF.

### (2.8) Filter Circuit

As illustrated in FIG. 4, the filter circuit 40 includes an input terminal 411, an output terminal 412, and a plurality of functional elements. The plurality of functional elements includes a plurality of (e.g., three in the example of FIG. 4) inductors L0, L1, and L2, and a plurality of (e.g., two in the example of FIG. 4) capacitors C1 and C2.

The input terminal 411 is an input terminal for a voltage selected by the supply modulator 30. That is, the input terminal 411 is a terminal for receiving the voltage selected from the plurality of voltages V1 to V4. Note that in the example of FIG. 4, the input terminal 411 is connected to the output terminal 310 of the supply modulator 30 with the band select switch circuit 50 interposed therebetween.

The output terminal 412 is a terminal to which a voltage filtered by the filter circuit 40 is outputted. The voltage outputted from the output terminal 412 of the filter circuit 40 is the power supply voltage Vcc supplied to the power amplifier 2.

The inductor L0 is connected between the input terminal 411 and the output terminal 412. In an example, one end (e.g., first end) of the inductor L0 is connected to the input terminal 411, and another end (e.g., second end) of the inductor L0 is connected to the output terminal 412.

The inductor L1 and the capacitor C1 are connected in series between the one end of the inductor L0 and the ground. In an example, one end (e.g., first end) of the inductor L1 is connected to the one end of the inductor L0, another end (e.g., second end) of the inductor L1 is connected to one of two electrodes of the capacitor C1, and another electrode of the two electrodes of the capacitor C1 is connected to the ground.

The inductor L2 and the capacitor C2 are connected in series between the other end of the inductor L0 and the ground. In an example, one end (e.g., first end) of the inductor L2 is connected to the other end of the inductor L0, another end (e.g., second end) of the inductor L2 is connected to one of two electrodes of the capacitor C2, and another electrode of the two electrodes of the capacitor C2 is connected to the ground.

The filter circuit 40 filters an output voltage of the supply modulator 30. The filter circuit 40 includes a low pass filter, for example. This allows the filter circuit 40 to reduce radio frequency components included in the power supply voltage Vcc. For example, when a predetermined band is a frequency band for FDD (or Frequency Division Duplex), the filter circuit 40 is configured to reduce components in a downlink operation band of the predetermined band.

Filter characteristics of the filter circuit 40 have two attenuation poles. A frequency of one of the two attenuation poles is determined by a circuit constant of each of the first inductor L1 and the first capacitor C1. In addition, a frequency of the other attenuation pole of the two attenuation poles is determined by a circuit constant of each of the second inductor L2 and the second capacitor C2.

The filter circuit 40 reduces the amplitude of the spike-like voltage of the output voltage outputted from the supply modulator 30. That is, by including the filter circuit 40, the power supply circuit 1 can reduce a waveform distortion in output voltages outputted from the supply modulator 30, thus being able to reduce the radio frequency components of the above output voltage. This allows the power supply circuit 1 to reduce the noise included in the power supply voltage Vcc, thus making it possible to reduce the noise entering the power amplifier 2 from the power supply circuit 1.

### (2.9) Digital Control Circuit

As illustrated in FIG. 5, the digital control circuit 60 includes a first controller 61, a second controller 62, two capacitors C81 and C82, and a plurality of control terminals, such as four control terminals 601 to 604. The four control terminals 601 to 604 of the digital control circuit 60 are connected one-to-one to a plurality of second control terminals, such as four second control terminals T5 shown in FIG. 2 and included in the radio frequency system 200. Therefore, the four control terminals 601 to 604 of the digital control circuit 60 are connected to a RF signal processing circuit, such as the RF signal processing circuit 51 shown in FIG. 2 of the communication device 7.

The first controller 61 receives a source-synchronous digital control signal from the RF signal processing circuit 51 via the control terminals 601 and 602, processes the above digital control signal, and generates the control signal Sg1 and the control signal Sg2.

The first controller 61 uses a set of a clock signal Sg7 and a data signal Sg8 as digital control signals for the pre-regulator circuit 10 and the switched-capacitor circuit 20. The clock signal Sg7 is inputted to the first controller 61 via the control terminal 601. The data signal Sg8 is inputted to the first controller 61 via the control terminal 602.

The second controller 62 processes digitally controlled level signals DCL1 and DCL2, which are the digital control signals received from the RF signal processing circuit 51 via the control terminals 603 and 604, to generate the control signal Sg3. The digitally controlled level signals DCL1 and DCL2 correspond to envelope signals.

Each of the digitally controlled level signals DCL1 and DCL2 is a one-bit signal. The voltages V1 to V4 are each represented by a combination of two one-bit signals. For example, V1, V2, V3, and V4 are represented by “00”, “01”, “10”, and “11”, respectively. A gray code may be used to represent a voltage level. Note that in the above case, the two digitally controlled level signals are used to control the supply modulator 30, but the number of the digitally controlled level signals is not limited to two. For example, any number, such as one or three or more, of the digitally controlled level signals may be used, depending on the number of voltage levels that can be selected by the supply modulator 30. In addition, digital control signals used to control the supply modulator 30 are not limited to the digitally controlled level signals.

In an exemplary aspect, the capacitor C81 is connected between the first controller 61 and the ground. For example, the capacitor C81 is connected between a power supply line that supplies electric power to the first controller 61 and the ground, and acts as a bypass capacitor. The capacitor C82 is connected between the second controller 62 and the ground. For example, the capacitor C82 is connected between a power supply line that supplies electric power to the second controller 62 and the ground and acts as a bypass capacitor.

### (3) Structure of Tracker Module

As illustrated in FIG. 1, the tracker module 100 includes the module laminate 12 and a plurality of circuit components 8 disposed on the module laminate 12. The plurality of circuit components 8 includes the first IC chip 81, the second IC chip 82, a first circuit component 83, and a second circuit component 84. In addition, the tracker module 100 further includes a plurality of external connection terminals 18, a resin layer 14, and a shield electrode layer 16.

### (3.1) Module Laminate

In an exemplar aspect, as illustrated in FIG. 1, the module laminate 12 has a first principal surface 121 and a second principal surface 122 that face each other in a thickness direction D1 of the module laminate 12. For purposes of this disclosure, the phrase “face each other” means facing geometrically and not physically. Moreover, in the plan view in the thickness direction D1 of the module laminate 12, an outer edge of the module laminate 12 has, for example, a rectangular shape, but may have any shape other than the rectangular shape. The module laminate 12 is, for example, a multi-layer substrate in which a plurality of dielectric layers and a plurality of conductive layers (not illustrated) are laminated. Examples of materials of the respective conductive layers include copper. The plurality of conductive layers includes a ground layer. The ground layer of the module laminate 12 is electrically connected to at least one external ground terminal included in the plurality of external connection terminals 18, with a via conductor unit 124 of the module laminate 12, or the like, interposed therebetween.

The module laminate 12 is, for example, an LTCC (or Low Temperature Co-fired Ceramics) substrate. Note that the module laminate 12 is not limited to the LTCC substrate, but may be, for example, a printed wiring board, an HTCC (or High Temperature Co-fired Ceramics) substrate, a resin multi-layer substrate, or a component-embedded board.

Here, the module laminate 12 is a substrate separate from a module laminate 13 to be described below. Then, a first circuit component 91 including the power amplifier 2 is disposed on the module laminate 13. That is, in Embodiment 1, the module laminate 13 is a first module laminate, and the module laminate 12 is a second module laminate. Note that the first module laminate where the power amplifier 2 is disposed is not limited to the module laminate 13, but may be a motherboard 11 included in the communication device 7.

### (3.2) First IC Chip

As illustrated in FIG. 1, the first IC chip 81 is disposed on the module laminate 12. “The first IC chip 81 is disposed on the module laminate 12” includes mechanical connection of the first IC chip 81 to the module laminate 12 and electrical connection of the first IC chip 81 to the module laminate 12. The first IC chip 81 is disposed on the first principal surface 121 of the module laminate 12. The first IC chip 81 is, for example, a Si-based IC chip including a silicon substrate. A Si-based IC chip may have a SOI (or Silicon on Insulator) substrate in place of the silicon substrate. The first IC chip 81 is not limited to the Si-based IC chip, and may be, for example, a GaAs-based IC chip, a SiGe-based IC chip, or a GaN-based IC chip.

An outer edge of the first IC chip 81 has a rectangular shape with four sides in the plan view in the thickness direction D1 of the module laminate 12.

The first IC chip 81 includes the switched-capacitor circuit 20 and the supply modulator 30. In an example, the first IC chip 81 includes a plurality of the switches, such as S11 to S14, S21 to S24, S31 to S34, S41 to S44 shown in FIG. 4 of the switched-capacitor circuit 20 and a plurality of the switches, such as switches S51 to S54 shown in FIG. 4 of the supply modulator 30.

In the first IC chip 81, each of the plurality of switches S11 to S14, S21 to S24, S31 to S34, S41 to S44, and S51 to S54 is, for example, a MOSFET (or Metal Oxide Semiconductor Field Effect Transistor).

Here, the tracker module 100 further includes a signal generation unit 70. As illustrated in FIG. 1, the signal generation unit 70 is included in the first IC chip 81. That is, the signal generation unit 70 is disposed on the module laminate 12. In an exemplary aspect, the signal generation unit 70 is disposed on the first principal surface 121 of the module laminate 12. The signal generation unit 70 generates a control signal for controlling a supply modulator, such as the supply modulator 30 shown in FIG. 2, based on the envelope of the radio frequency signal. The signal generation unit 70 includes an algorithm for optimally controlling the power supply circuit 1 and the control circuit 4 described above. The control signal generated by the signal generation unit 70 is outputted to the supply modulator 30. This control signal controls ON/OFF of the plurality of switches, such as the switches S51 to S54 shown in FIG. 4.

### (3.3) Second IC Chip

As I illustrated in FIG. 1, the second IC chip 82 is disposed in the module laminate 12. That is, the second IC chip 82 is disposed in the module laminate 12 where the first IC chip 81 is disposed. In an example, the second IC chip 82 is disposed on the first principal surface 121 of the module laminate 12. That is, the first IC chip 81 and the second IC chip 82 are disposed on the first principal surface 121 of the module laminate 12. In Embodiment 1, the first IC chip 81 and the second IC chip 82 are integrated.

An outer edge of the second IC chip 82 has a rectangular shape with four sides in the plan view in the thickness direction D1 of the module laminate 12. The second IC chip 82 includes the control circuit 4.

### (3.4) First Circuit Component

As illustrated in FIG. 1, the first circuit component 83 is disposed on the module laminate 12. In an exemplary aspect, the first circuit component 83 is disposed on the first principal surface 121 of the module laminate 12. In addition, in the plan view in the thickness direction D1 of the module laminate 12, the first IC chip 81 and the first circuit component 83 are adjacent to each other. For purposes of this disclosure, the phrase “the first IC chip 81 and the first circuit component 83 are adjacent to each other” means that in the plan view in the thickness direction D1 of the module laminate 12, the first IC chip 81 and the first circuit component 83 are disposed on the first principal surface 121 of the module laminate 12, with no other circuit component disposed between the first IC chip 81 and the first circuit component 83.

An outer edge of the first circuit component 83 has a rectangular shape with four sides in the plan view in the thickness direction D1 of the module laminate 12.

The first circuit component 83 includes, for example, the capacitor C23 of the switched-capacitor circuit 20. The first circuit component 83 is, for example, a chip capacitor.

### (3.5) Second Circuit Component

As illustrated in FIG. 1, the second circuit component 84 is disposed on the module laminate 12. In an exemplary aspect, the second circuit component 84 is disposed on the first principal surface 121 of the module laminate 12. In addition, in the plan view in the thickness direction D1 of the module laminate 12, the first IC chip 81 and the second circuit component 84 are adjacent to each other.

An outer edge of the second circuit component 84 has a rectangular shape with four sides in the plan view in the thickness direction D1 of the module laminate 12.

The second circuit component 84 includes, for example, the capacitor C21 of the switched-capacitor circuit 20. The second circuit component 84 is, for example, a chip capacitor.

### (3.6) External Connection Terminal

The plurality of external connection terminals 18 illustrated in FIG. 1 includes an input terminal, such as the input terminal 181 shown in FIG. 2, an output terminal, such as the output terminal 182 shown in FIG. 2, a plurality of (e.g., four) input control terminals, such as the input control terminal 183 illustrated in FIG. 2, the control terminal 184, and the ground terminal (not illustrated).

The input terminal 181 is connected to the input terminal 110 of the pre-regulator circuit 10. The input terminal 181 is a terminal connected to the direct current power source 71 with the power supply connection terminal T4 of the radio frequency system 200 interposed therebetween. That is, the input terminal 110 of the pre-regulator circuit 10 is connected to the direct current power source 71 with the input terminal 181 interposed therebetween.

According to an exemplary aspect, the output terminal 182 is connected to the output terminal 412 of the filter circuit 40. The output terminal 182 is a terminal to which the power supply voltage Vcc is outputted, and is connected to the power supply terminal of the power amplifier 2.

The four input control terminals 183 are connected to the control terminals 601 to 604 of the digital control circuit 60. The four input control terminals 183 are connected to the RF signal processing circuit 51 of the signal processing circuit 5 with the four second control terminals T5 of the radio frequency system 200 interposed therebetween.

The control terminal 184 is connected to the control circuit 4. The control terminal 184 is a terminal to which a control signal for controlling the power amplifier 2 is outputted, and is connected to the control terminal of the power amplifier 2.

A plurality of the ground terminals is a terminal to which a ground potential is given.

### (3.7) Resin Layer

As illustrated in FIG. 1, the resin layer 14 is disposed on the first principal surface 121 of the module laminate 12, and covers some of each of the plurality of circuit components 8 included in the tracker module 100 and the first principal surface 121 of the module laminate 12. As described above, the plurality of circuit components 8 includes the first IC chip 81, the second IC chip 82, the first circuit component 83, and the second circuit component 84. The resin layer 14 includes a resin (e.g., epoxy resin). The resin layer 14 may include a filler in addition to the resin. The resin layer 14 has electrical insulation properties.

### (3.8) Shield Electrode Layer

As illustrated in FIG. 1, the shield electrode layer 16 covers the resin layer 14 and the module laminate 12. In an exemplary aspect, the shield electrode layer 16 covers a principal surface 141 and an outer peripheral surface 143 of the resin layer 14, and an outer peripheral surface 123 of the module laminate 12.

The shield electrode layer 16 has conductive properties. In the tracker module 100, the shield electrode layer 16 is a shield layer provided to provide electromagnetic shield inside and outside of the tracker module 100. The shield electrode layer 16 is in contact with at least a part of an outer peripheral surface of the ground layer of the module laminate 12. This configuration makes the potential of the shield electrode layer 16 equal to that of the ground layer. Although the shield electrode layer 16 has a multi-layer structure in which a plurality of metal layers is laminated, the shield electrode layer 16 is not limited to the multi-layer structure and may be a single metal layer. The metal layer includes one or more types of metals.

### (4) Structure of Radio Frequency Module

In an exemplary aspect, as illustrated in FIG. 1, a radio frequency module 300 includes the module laminate 13 and a plurality of circuit components 9 disposed on the module laminate 13. The plurality of circuit components 9 further includes the first circuit component 91, a second circuit component 92, a third circuit component 93, and a fourth circuit component 94. In addition, the radio frequency module 300 further includes a plurality of external connection terminals 19, a first resin layer 15, a shield electrode layer 17, and a second resin layer 23.

### (4.1) Module Laminate

In an exemplary aspect, as illustrated in FIG. 1, the module laminate 13 has a first principal surface 131 and a second principal surface 132 that face each other in a thickness direction D1 of the module laminate 13. In a plan view in the thickness direction D1 of the module laminate 13, an outer edge of the module laminate 13 has, for example, a rectangular shape, but may have a shape other than the rectangular shape. The module laminate 13 is, for example, a multi-layer substrate in which a plurality of dielectric layers and a plurality of conductive layers (not illustrated) are laminated. Examples of materials of the respective conductive layers include copper. The plurality of conductive layers includes a ground layer. The ground layer of the module laminate 13 is electrically connected to at least one external ground terminal included in the plurality of external connection terminals 19, with a via conductor unit 134 of the module laminate 13, or the like, interposed therebetween.

The module laminate 13 is, for example, an LTCC substrate. Note that the module laminate 13 is not limited to the LTCC substrate, and may be, for example, a printed wiring board, an HTCC substrate, a resin multi-layer substrate, or a component-embedded board.

### (4.2) First Circuit Component

As illustrated in FIG. 1, the first circuit component 91 is disposed on the module laminate 13. In an exemplary aspect, the first circuit component 91 is disposed on the first principal surface 131 of the module laminate 13. The first circuit component 91 includes the power amplifier 2, for example. An outer edge of the first circuit component 91 has a rectangular shape with four sides in the plan view in the thickness direction D1 of the module laminate 13.

### (4.3) Second Circuit Component

As illustrated in FIG. 1, the second circuit component 92 is disposed on the module laminate 13. In an exemplary aspect, the second circuit component 92 is disposed on the second principal surface 122 of the module laminate 12. The second circuit component 92 includes, for example, the low noise amplifier described above. An outer edge of the second circuit component 92 has a rectangular shape with four sides in the plan view in the thickness direction D1 of the module laminate 13.

### (4.4) Third Circuit Component

As illustrated in FIG. 1, the third circuit component 93 is disposed on the module laminate 13. In an exemplary aspect, the third circuit component 93 is disposed on the first principal surface 131 of the module laminate 13. In addition, in the plan view in the thickness direction D1 of the module laminate 12, the first circuit component 91 and the third circuit component 93 are adjacent to each other on the first principal surface 131 of the module laminate 13. The third circuit component 93 includes a capacitor, for example. The capacitor is the capacitor that forms a part of the input matching circuit provided between the above-described low noise amplifier and the receiving filter. An outer edge of the third circuit component 93 has a rectangular shape with four sides in the plan view in the thickness direction D1 of the module laminate 13.

### (4.5) Fourth Circuit Component

As illustrated in FIG. 1, the fourth circuit component 94 is disposed on the module laminate 13. In an exemplary aspect, the fourth circuit component 94 is disposed on the second principal surface 132 of the module laminate 13. In addition, in the plan view in the thickness direction D1 of the module laminate 13, the second circuit component 92 and the fourth circuit component 94 are adjacent to each other on the second principal surface 132 of the module laminate 13. The fourth circuit component 94 includes a capacitor, for example. The capacitor is the capacitor that forms a part of the output matching circuit (not illustrated) provided between the power amplifier 2 and the filter 3. An outer edge of the fourth circuit component 94 has a rectangular shape with four sides in the plan view in the thickness direction D1 of the module laminate 13.

### (4.6) External Connection Terminal

In an exemplary aspect, the plurality of external connection terminals 19 includes the antenna terminal T1, the signal input terminal T2, a signal output terminal (not illustrated), and the plurality of ground terminals (not illustrated). The antenna terminal T1 is connected to the antenna 6. The signal input terminal T2 and the signal output terminal are connected to the signal processing circuit 5. The plurality of ground terminals is a terminal to which the ground potential is applied.

The plurality of external connection terminals 19 is disposed on the second principal surface 132 of the module laminate 13. Each of the plurality of external connection terminals 19 is connected to the module laminate 13 with corresponding connection terminals 22 of the plurality of connection terminals 22 interposed therebetween.

### (4.7) First Resin Layer

In an exemplary aspect, as illustrated in FIG. 1, the first resin layer 15 is disposed on the first principal surface 131 of the module laminate 13, and covers some of each of the first circuit component 91 and the third circuit component 93, and the first principal surface 131 of the module laminate 13. The first resin layer 15 includes a resin (e.g., epoxy resin). The first resin layer 15 may include a filler in addition to the resin. The first resin layer 15 has the electrical insulation properties.

### (4.8) Shield Electrode Layer

In an exemplary aspect, as illustrated in FIG. 1, the shield electrode layer 17 covers the first resin layer 15 and the module laminate 13. In an exemplary aspect, the shield electrode layer 17 covers a principal surface 151 and an outer peripheral surface 153 of the first resin layer 15, and an outer peripheral surface 133 of the module laminate 13.

The shield electrode layer 17 has the conductive properties. In the radio frequency module 300, the shield electrode layer 17 is a shield layer provided to provide the electromagnetic shield inside and outside of the radio frequency module 300. The shield electrode layer 17 is in contact with at least a part of an outer peripheral surface of the ground layer of the module laminate 13. This configuration makes the potential of the shield electrode layer 17 equal to that of the ground layer. Although the shield electrode layer 17 has a multi-layer structure in which a plurality of metal layers is laminated, the shield electrode layer 17 is not limited to the multi-layer structure and may be a single metal layer. The metal layer includes one or more types of metals.

### (4.9) Second Resin Layer

In an exemplary aspect, as illustrated in FIG. 1, the second resin layer 23 is disposed on the second principal surface 132 of the module laminate 13, and covers an outer peripheral surface of each of the second circuit component 92 and the fourth circuit component 94, an outer peripheral surface of each of the plurality of connection terminals 22, and the second principal surface 132 of the module laminate 13. The second resin layer 23 includes a resin (e.g., epoxy resin). The second resin layer 23 may include a filler in addition to the resin. The second resin layer 23 has the electrical insulation properties. Note that the second resin layer 23 may be made of a same material as that of the first resin layer 15 or may be made of a different material.

### (5) Structure of Radio Frequency System

In an exemplary aspect, as illustrated in FIG. 1, the radio frequency system 200 includes the motherboard 11 and a plurality of electronic components disposed on the motherboard 11. The motherboard 11 is a printed wiring board, for example. The plurality of electronic components includes the tracker module 100, the radio frequency module 300, the power inductor L71, and the RFIC 51.

### (5.1) Motherboard

As illustrated in FIG. 1, the motherboard 11 has a first principal surface 101 and a second principal surface 102 that face each other in a thickness direction D1 of the motherboard 11. In a plan view in the thickness direction of the motherboard 11, an outer edge of the motherboard 11 has, for example, a rectangular shape, but may have any shape other than the rectangular shape.

### (5.2) Tracker Module

The tracker module 100 is disposed on the motherboard 11. In an exemplary aspect, the tracker module 100 is disposed on the first principal surface 101 of the motherboard 11. In an example, the tracker module 100 is disposed on the first principal surface 101 of the motherboard 11 with the plurality of external connection terminals 18 and the plurality of bumps 104 interposed therebetween.

### (5.3) Radio Frequency Module

The radio frequency module 300 is disposed on the motherboard 11. In an exemplary aspect, the radio frequency module 300 is disposed on the first principal surface 101 of the motherboard 11. In an example, the radio frequency module 300 is disposed on the first principal surface 101 of the motherboard 11 with the plurality of external connection terminals 19 and the plurality of bumps 104 interposed therebetween.

### (5.4) Power Inductor

The power inductor L71 is disposed on the motherboard 11. In an exemplary aspect, the power inductor L71 is disposed on the first principal surface 101 of the motherboard 11.

An outer edge of the power inductor L71 has a rectangular shape with four sides in the plan view in the thickness direction D1 of the motherboard 11. In the thickness direction D1 of the motherboard 11, the power inductor L71 disposed on the motherboard 11 has a height higher than that of the tracker module 100.

### (5.5) RFIC

The RFIC 51 is disposed on the motherboard 11. In an exemplary aspect, the RFIC 51 is disposed on the first principal surface 101 of the motherboard 11. In an example, the RFIC 51 includes a plurality of external connection terminals 21, and is disposed on the first principal surface 101 of the motherboard 11 with the plurality of external connection terminals 21 and the plurality of bumps 104 interposed therebetween.

An outer edge of the RFIC 51 has a rectangular shape with four sides in the plan view in the thickness direction D1 of the motherboard 11.

### (5.6) Layout

As illustrated in FIG. 1, the tracker module 100, the radio frequency module 300, the power inductor L71, and the RFIC 51 are disposed on the first principal surface 101 of the motherboard 11. The tracker module 100 and the radio frequency module 300 are positioned side-by-side in a second direction D2 orthogonal to a first direction D1 that is the thickness direction of the motherboard 11. In the second direction D2, the power inductor L71 is located between the tracker module 100 and the radio frequency module 300. In the second direction D2, the RFIC 51 is located on the opposite side of the tracker module 100 from the power inductor L71. That is, on the first principal surface 101 of the motherboard 11, the tracker module 100, the radio frequency module 300, the power inductor L71, and the RFIC 51 are positioned side-by-side, from one end side (e.g., a left side of FIG. 1) to another end side (e.g., a right side of FIG. 1) in the second direction D2, in the order of the RFIC 51, the tracker module 100, the power inductor L71, and the radio frequency module 300.

### (6) Structure of Communication Device

In an exemplary aspect, the communication device 7 includes the radio frequency system 200, the signal processing circuit 5 disposed on the motherboard 11 of the radio frequency system 200, and the antenna 6. Note that the communication device 7 may include a second motherboard where the radio frequency system 200 and the signal processing circuit 5 are disposed, in addition to a first motherboard that is the motherboard 11 of the radio frequency system 200.

### (7) Layout of External Connection Terminal of Tracker Module

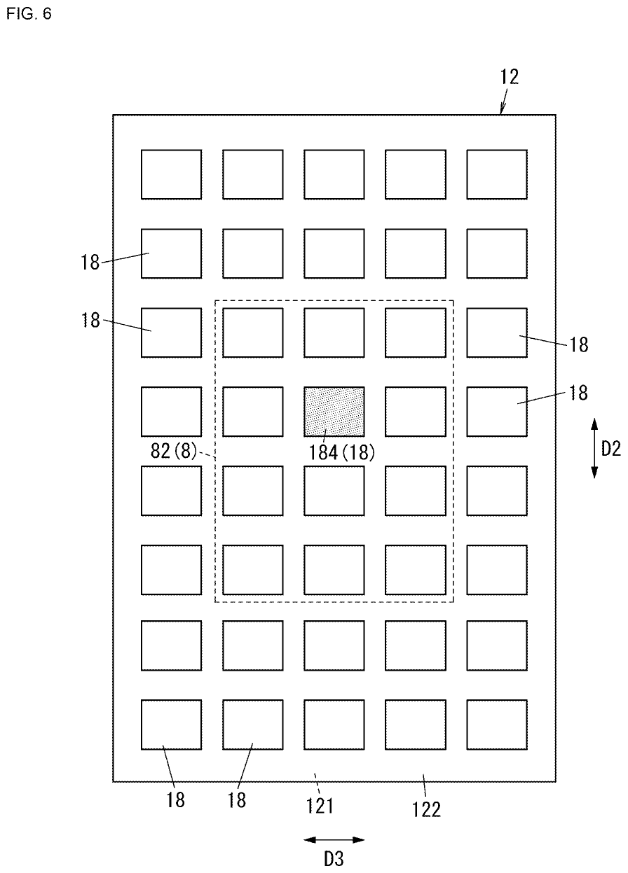

In an exemplary aspect, a description of a layout of the external connection terminals 18 of the tracker module 100 can be provided with reference to FIG. 6.

As described above, the tracker module 100 includes the plurality of external connection terminals 18. As illustrated in FIG. 6, the plurality of external connection terminals 18 is arranged in a matrix along the second direction D2 and a third direction D3 on the second principal surface 122 of the module laminate 12. The plurality of external connection terminals 18 includes the control terminal 184. The control terminal 184 is connected to a control circuit, such as the control circuit 4 shown in FIG. 2. The second direction D2 and the third direction D3 are directions orthogonal to the thickness direction D1 of the module laminate 12.

Here, as described above, the control circuit 4 is included in the second IC chip 82 (or first IC chip 81). Then, as illustrated in FIG. 6, the control terminal 184 overlaps the second IC chip 82 in the thickness direction D1 of the module laminate 12. “The control terminal 184 overlaps the second IC chip 82 in the thickness direction D1 of the module laminate 12” includes the all of the control terminal 184 overlapping all of the second IC chip 82 in the thickness direction D1 of the module laminate 12, overlapping of all of the control terminal 184 with a part of the second IC chip 82, overlapping of a part of the control terminal 184 with all of the second IC chip 82, and overlapping of a part of the control terminal 184 with a part of the second IC chip 82. That is, the phrase “The control terminal 184 overlaps the second IC chip 82 in the thickness direction D1 of the module laminate 12” means that at least a part of the control terminal 184 overlaps at least a part of the second IC chip 82. This configuration shortens a wiring length between the second IC chip 82 (or control circuit 4) and the control terminal 184.

### (8) Effects

In the tracker module 100 according to Embodiment 1, the second IC chip 82 (or first IC chip 81) including the control circuit 4 is disposed on the module laminate 12, as illustrated in FIG. 1. This configuration reduces a size of an entire transmission system including the power amplifier 2, as compared with a case in which the second IC chip 82 is not disposed on the module laminate 12.

In addition, in the tracker module 100 according to Embodiment 1, the first IC chip 81 and the second IC chip 82 are disposed on the first principal surface 121 of the module laminate 12. This allows the tracker module 100 to be made thinner than that in a case in which the first IC chip 81 and the second IC chip 82 are disposed on separate principal surfaces.

In addition, in the tracker module 100 according to Embodiment 1, the first IC chip 81 and the second IC chip 82 are integrated. This configuration reduces a surface area of the module laminate 12, as compared with a case in which the first IC chip 81 and the second IC chip 82 are separate bodies.

In addition, in the tracker module 100 according to Embodiment 1, the signal generation unit 70 is disposed in the module laminate 12. This configuration reduces the size of the entire transmission system including the power amplifier 2, as compared with a case in which the signal generation unit 70 is not disposed in the module laminate 12.

In the tracker module 100 according to Embodiment 1, in an exemplar aspect, it is possible to further reduce the size of the entire transmission system including the power amplifier 2 because the signal generation unit 70 is included in the first IC chip 81.

In addition, in the tracker module 100 according to Embodiment 1, the control terminal 184 is disposed on the module laminate 12 so as to overlap the second IC chip 82 in the thickness direction D1 of the module laminate 12. This configuration shortens the wiring length between the second IC chip 82 and the control terminal 184.

In addition, it is possible to reduce the size of the entire transmission system including the power amplifier 2 because the radio frequency system 200 and the communication device 7 according to Embodiment 1 include the tracker module 100.

### (9) Modification of Embodiment 1

Modifications of Embodiment 1 can be listed below.

In an exemplary aspect, the first IC chip 81 may include at least one of the plurality of switches S11 to S14, S21 to S24, S31 to S34, or S41 to S44 with respect to the switched-capacitor circuit 20. In addition, it may be sufficient when the first IC chip 81 includes at least one of the plurality of switches S51 to S54 with respect to the supply modulator 30.

In addition, the pre-regulator circuit 10, the switched-capacitor circuit 20, the supply modulator 30, the band select switch circuit 50, and the filter circuit 40 are not limited to the circuit configuration illustrated in FIG. 4.

For example, in FIG. 4, the switched-capacitor circuit 20 is configured to be able to supply the voltages at the four discrete voltage levels V1, V2, V3, and V4, but the switched-capacitor circuit 20 is not limited to the configuration capable of supplying the voltages at the four discrete voltage levels. The switched-capacitor circuit 20 may be configured to be able to supply voltages at any number, such as two or more discrete voltage levels. For example, when the switched-capacitor circuit 20 is configured to be able to supply voltages at the two discrete voltage levels, the switched-capacitor circuit 20 can at least include the capacitors C12 and C15, and the switches S21, S22, S31, S32, S23, S24, S33, and S34.

In addition, the configuration of the supply modulator 30 is not limited to the configuration illustrated in FIG. 4. The switches S51 to S54, in an exemplary aspect, may have any configuration as far as they can select any of the four input terminals 311 to 314 and connect it to the output terminal 310. For example, the supply modulator 30 may further include a switch connected between the switches S51 to S53, the switch S54, and the output terminal 310. In addition, for example, the supply modulator 30 may further include a switch connected between the switches S51 and S52, the switches S53 and S54, and the output terminal 310.

In addition, for example, when one voltage is selected from voltages at the two discrete voltage levels, the supply modulator 30 may have only to include at least the switches S52 and S53.

In addition, although the filter circuit 40 illustrated in FIG. 4 forms the low pass filter, the filter circuit 40 is not limited to the case in which it forms the low pass filter, and may form a band pass filter or a high pass filter.

In addition, digital control signals processed by the first controller 61 are not limited to source-synchronous digital control signals. For example, the first controller 61 may process clock-embedded digital control signals.

In addition, although one set of clock signals and data signals is used as digital control signals for the pre-regulator circuit 10 and the switched-capacitor circuit 20, a set of clock signals and data signals may be separately used as the digital control signals for the pre-regulator circuit 10 and the switched-capacitor circuit 20.

In an exemplary aspect, at least one of the tracker module 100, the radio frequency module 300, the power inductor L71, and the RFIC 51 are disposed on the first principal surface 101 of the motherboard 11, and rest of the tracker module 100, the radio frequency module 300, the power inductor L71, and the RFIC 51 may be disposed on the second principal surface 102 of the motherboard 11.

The first IC chip 81 and the second IC chip 82 may be disposed on the second principal surface 122 of the module laminate 12. That is, it may be sufficient if the first IC chip 81 and the second IC chip 82 are disposed on the first principal surface 121 or the second principal surface 122 of the module laminate 12.

The tracker module 100 and the radio frequency system 200 according to each of the modifications described above also achieve the effects similar to those of the tracker module 100 and the radio frequency system 200 according to Embodiment 1.

### Embodiment 2

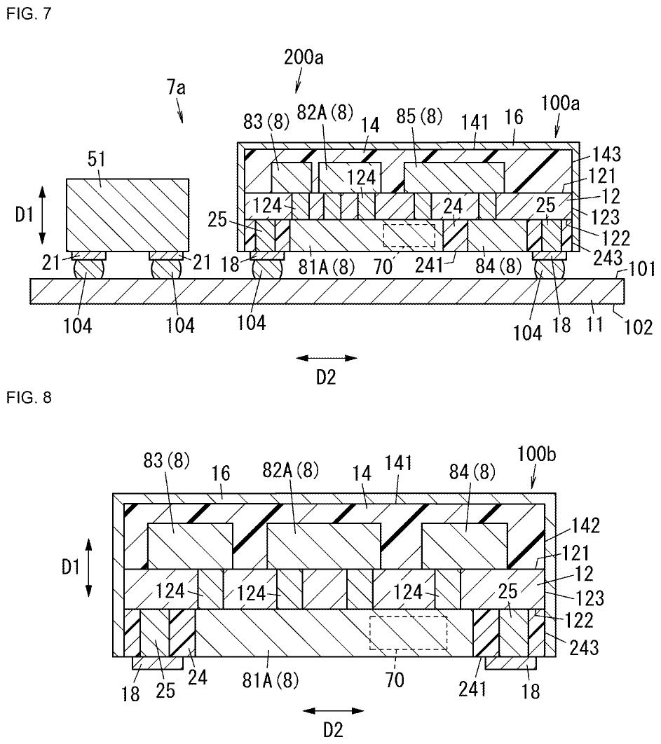

A description of a tracker module 100a, a radio frequency system 200a, and a communication device 7a according to Embodiment 2 can be provided with reference to FIG. 7. The same reference numerals can be assigned to components of the tracker module 100a, the radio frequency system 200a, and the communication device 7a according to Embodiment 2 similar to those of the tracker module 100, the radio frequency system 200, and the communication device 7 that are shown in FIG. 1 according to Embodiment 1, and a description thereof will be omitted.

### (1) Structure of Tracker Module

In an exemplary aspect, a description of the structure of the tracker module 100a according to Embodiment 2 can be provided with reference to FIG. 7.

As illustrated in FIG. 7, the tracker module 100a according to Embodiment 2 includes the module laminate 12 and the plurality of circuit components 8 disposed on the module laminate 12. The plurality of circuit components 8 includes a first IC chip 81A, a second IC chip 82A, the first circuit component 83, the second circuit component 84, and a third circuit component 85. In addition, the tracker module 100a further includes the plurality of external connection terminals 18, the resin layer 14 (hereinafter also referred to as a “first resin layer 14”), the shield electrode layer 16, and a second resin layer 24.

The first IC chip 81A is disposed on the second principal surface 122 of the module laminate 12. The first IC chip 81A includes the plurality of switches S11 to S14, S21 to S24, S31 to S34, and S41 to S44 included in the switched-capacitor circuit 20, the plurality of switches S51 to S54 of the supply modulator 30, and the signal generation unit 70.

The second IC chip 82A is disposed on the first principal surface 121 of the module laminate 12. The second IC chip 82A includes the control circuit 4. That is, in the tracker module 100a according to Embodiment 2, the first IC chip 81A and the second IC chip 82A are separate bodies.

In an exemplary aspect, the first circuit component 83 is disposed on the first principal surface 121 of the module laminate 12. In the example of FIG. 7, the second IC chip 82A and the first circuit component 83 are adjacent to each other on the first principal surface 121 of the module laminate 12. Similarly to the first circuit component 83 according to Embodiment 1, the first circuit component 83 includes, for example, the capacitor C23 of the switched-capacitor circuit 20.

In an exemplary aspect, the second circuit component 84 is disposed on the second principal surface 122 of the module laminate 12. In the example of FIG. 7, the first IC chip 81A and the second circuit component 84 are adjacent to each other on the second principal surface 122 of the module laminate 12. Similarly to the second circuit component 84 according to Embodiment 1, the second circuit component 84 includes, for example, the capacitor C21 of the switched-capacitor circuit 20.

The third circuit component 85 is disposed on the first principal surface 121 of the module laminate 12. In the example of FIG. 7, the second IC chip 82A and the third circuit component 85 are adjacent to each other on the first principal surface 121 of the module laminate 12. The third circuit component 85 includes, for example, the power amplifier 2. Note that the third circuit component 85 may also include a low noise amplifier together with the power amplifier 2.

The plurality of external connection terminals 18 is disposed on the second principal surface 122 of the module laminate 12. Each of the plurality of external connection terminals 18 is connected to the module laminate 12 with a corresponding connection terminal 25 of a plurality of the connection terminals 25 interposed therebetween.

As illustrated in FIG. 7, the second resin layer 24 is disposed on the second principal surface 122 of the module laminate 12, and covers an outer peripheral surface of each of the first IC chip 81A and the second circuit component 84, an outer peripheral surface of the connection terminal 25, and the second principal surface 122 of the module laminate 12. The second resin layer 24 includes a resin (e.g., epoxy resin). The second resin layer 24 may include a filler, in addition to the resin. The second resin layer 24 has the electrical insulation properties. Note that the second resin layer 24 may be made of a same material as that of the first resin layer 14 or may be made of a different material.

### (2) Structure of Radio Frequency System

In an exemplary aspect, a description of the structure of the radio frequency system 200a according to Embodiment 2 can be provided with reference to FIG. 7.

As illustrated in FIG. 7, the radio frequency system 200a according to Embodiment 2 includes the motherboard 11, the tracker module 100a, and the RFIC 51.

The tracker module 100a is disposed on the first principal surface 101 of the motherboard 11. The RFIC 51 is disposed on the first principal surface 101 of the motherboard 11. The tracker module 100a and the RFIC 51 are positioned side-by-side in a second direction D2 on the first principal surface 101 of the motherboard 11. Here, in the radio frequency system 200a according to Embodiment 2, the power amplifier 2 included in the third circuit component 85 is disposed on the first principal surface 121 of the module laminate 12.

### (3) Structure of Communication Device

In an exemplary aspect, the communication device 7a includes the radio frequency system 200a, a signal processing circuit, such as the signal processing circuit 5 shown in FIG. 2, disposed on the motherboard 11 of the radio frequency system 200a, and an antenna, such as the antenna 6 shown in FIG. 2. Note that the communication device 7a may include a second motherboard where the radio frequency system 200a and the signal processing circuit 5 are disposed, in addition to a first motherboard that is the motherboard 11 of the radio frequency system 200a.

### (4) Effects

In the tracker module 100a according to Embodiment 2, the second IC chip 82A including the control circuit 4 is disposed on the first principal surface 121 of the module laminate 12. In addition, in the tracker module 100a according to Embodiment 2, the third circuit component 85 including the power amplifier 2 is disposed on the first principal surface 121 of the module laminate 12. This configuration reduces the size of the entire transmission system including the power amplifier 2, as compared with a case in which the second IC chip 82A and the third circuit component 85 are not disposed on the module laminate 12.

### Embodiment 3

A description of a tracker module 100b according to Embodiment 3 can be provided with reference to FIG. 8. The same reference numerals can be assigned to components of the tracker module 100b according to Embodiment 3 similar to those of the tracker module 100 that are shown in FIG. 1 according to Embodiment 1, and a description thereof will be omitted.

### (1) Structure of Tracker Module

In an exemplary aspect, a description of the structure of the tracker module 100b according to Embodiment 3 can be provided with reference to FIG. 8.

As illustrated in FIG. 8, the tracker module 100b according to Embodiment 3 includes the module laminate 12 and the plurality of circuit components 8 disposed on the module laminate 12. The plurality of circuit components 8 includes the first IC chip 81A, the second IC chip 82A, the first circuit component 83, and the second circuit component 84. In addition, the tracker module 100b further includes the plurality of external connection terminals 18, the first resin layer 14, the shield electrode layer 16, and the second resin layer 24.

The first IC chip 81A is disposed on the second principal surface 122 of the module laminate 12. The first IC chip 81A includes the plurality of switches S11 to S14, S21 to S24, S31 to S34, and S41 to S44 included in the switched-capacitor circuit 20, the plurality of switches S51 to S54 of the supply modulator 30, and the signal generation unit 70.

The second IC chip 82A is disposed on the first principal surface 121 of the module laminate 12. The second IC chip 82A includes the control circuit 4. That is, in the tracker module 100b according to Embodiment 3, the first IC chip 81A and the second IC chip 82A are separate bodies.

In an exemplary aspect, the first circuit component 83 is disposed on the first principal surface 121 of the module laminate 12. In the example of FIG. 8, the second IC chip 82A and the first circuit component 83 are adjacent to each other on the first principal surface 121 of the module laminate 12. Similarly to the first circuit component 83 according to Embodiment 1, the first circuit component 83 includes, for example, the capacitor C23 of the switched-capacitor circuit 20.

The second circuit component 84 is disposed on the first principal surface 121 of the module laminate 12. In the example of FIG. 8, the second IC chip 82A and the second circuit component 84 are adjacent to each other on the first principal surface 121 of the module laminate 12. Similarly to the second circuit component 84 according to Embodiment 1, the second circuit component 84 includes, for example, the capacitor C21 of the switched-capacitor circuit 20.

The plurality of external connection terminals 18 is disposed on the second principal surface 122 of the module laminate 12. Each of the plurality of external connection terminals 18 is connected to the module laminate 12 with the corresponding connection terminal 25 of the plurality of connection terminals 25 interposed therebetween.

### (2) Effects

In the tracker module 100b according to Embodiment 3, the second IC chip 82A including the control circuit 4 is disposed on the first principal surface 121 of the module laminate 12. This configuration reduces the size of the entire transmission system including the power amplifier 2, as compared with a case in which the second IC chip 82A is not disposed on the module laminate 12.

In addition, according to the tracker module 100b according to Embodiment 3, it is possible to radiate heat generated in the first IC chip 81A to the motherboard 11, because the first IC chip 81A that generates a large amount of heat is disposed on the second principal surface 122 of the module laminate 12.

### Embodiment 4

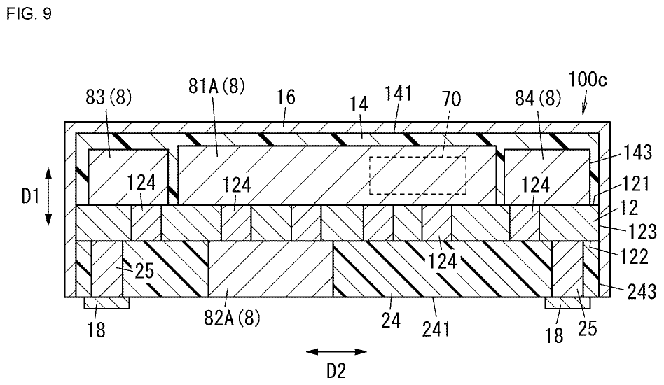

A description of a tracker module 100c according to Embodiment 4 can be provided with reference to FIG. 9. The same reference numerals can be assigned to components of the tracker module 100c according to Embodiment 4 similar to those of the tracker module 100 that are shown in FIG. 1 according to Embodiment 1, and a description thereof will be omitted.

### (1) Structure of Tracker Module

In an exemplary aspect, a description of the structure of the tracker module 100c according to Embodiment 4 can be provided with reference to FIG. 9.

As illustrated in FIG. 9, the tracker module 100c according to Embodiment 4 includes the module laminate 12 and the plurality of circuit components 8 disposed on the module laminate 12. The plurality of circuit components 8 includes the first IC chip 81A, the second IC chip 82A, the first circuit component 83, and the second circuit component 84. In addition, the tracker module 100c further includes the plurality of external connection terminals 18, the first resin layer 14, the shield electrode layer 16, and the second resin layer 24.

The first IC chip 81A is disposed on the first principal surface 121 of the module laminate 12. The first IC chip 81A includes the plurality of switches S11 to S14, S21 to S24, S31 to S34, and S41 to S44 included in the switched-capacitor circuit 20, the plurality of switches S51 to S54 of the supply modulator 30, and the signal generation unit 70.

According to an exemplary aspect, the second IC chip 82A is disposed on the second principal surface 122 of the module laminate 12. The second IC chip 82A includes the control circuit 4. That is, in the tracker module 100c according to Embodiment 4, the first IC chip 81A and the second IC chip 82A are separate bodies.

The first circuit component 83 is disposed on the first principal surface 121 of the module laminate 12. In the example of FIG. 9, the first IC chip 81A and the first circuit component 83 are adjacent to each other on the first principal surface 121 of the module laminate 12. Similarly to the first circuit component 83 according to Embodiment 1, the first circuit component 83 includes, for example, the capacitor C23 of the switched-capacitor circuit 20.

The second circuit component 84 is disposed on the first principal surface 121 of the module laminate 12. In the example of FIG. 9, the first IC chip 81A and the second circuit component 84 are adjacent to each other on the first principal surface 121 of the module laminate 12. Similarly to the second circuit component 84 according to Embodiment 1, the second circuit component 84 includes, for example, the capacitor C21 of the switched-capacitor circuit 20.

The plurality of external connection terminals 18 is disposed on the second principal surface 122 of the module laminate 12. Each of the plurality of external connection terminals 18 is connected to the module laminate 12 with the corresponding connection terminal 25 of the plurality of connection terminals 25 interposed therebetween.

### (2) Effects

According to an exemplary aspect, in the tracker module 100c according to Embodiment 4, the second IC chip 82A including the control circuit 4 is disposed on the second principal surface 122 of the module laminate 12. This configuration reduces the size of the entire transmission system including the power amplifier 2, as compared with a case in which the second IC chip 82A is not disposed on the module laminate 12.

In addition, in the tracker module 100c according to Embodiment 4, a surface of the first circuit component 83 cannot be cut. Thus, the first circuit component 83 is disposed on the first principal surface 121 of the module laminate 12. Therefore, by disposing the first IC chip 81A on the first principal surface 121 of the module laminate 12, it is possible to shorten a distance between the first IC chip 81A and the first circuit component 83.

### Reference Example 1

A description of a tracker module 100d, a radio frequency system 200d, and a communication device 7d according to Reference Example 1 can be provided with reference to FIG. 10. The same reference numerals will be assigned to components of the tracker module 100d, the radio frequency system 200d, and the communication device 7d according to Reference Example 1 similar to those of the tracker module 100, the radio frequency system 200, and the communication device 7 (See FIG. 1) according to Embodiment 1, and a description thereof will be omitted.

### (1) Structure of Tracker Module

In an exemplary aspect, a description of the structure of the tracker module 100d according to Reference Example 1 can be provided with reference to FIG. 10.

As illustrated in FIG. 10, the tracker module 100d according to Reference Example 1 includes the module laminate 12 and the plurality of circuit components 8 disposed on the module laminate 12. The plurality of circuit components 8 includes the first IC chip 81A, the first circuit component 83, and the second circuit component 84. In addition, the tracker module 100d further includes the plurality of external connection terminals 18, the resin layer 14, and the shield electrode layer 16.

The first IC chip 81A is disposed on the first principal surface 121 of the module laminate 12. The first IC chip 81A includes the plurality of switches S11 to S14, S21 to S24, S31 to S34, and S41 to S44 included in the switched-capacitor circuit 20, the plurality of switches S51 to S54 of the supply modulator 30, and the signal generation unit 70.

The first circuit component 83 is disposed on the first principal surface 121 of the module laminate 12. In the example of FIG. 10, the first IC chip 81A and the first circuit component 83 are adjacent to each other on the first principal surface 121 of the module laminate 12. Similarly to the first circuit component 83 according to Embodiment 1, the first circuit component 83 includes, for example, the capacitor C23 of the switched-capacitor circuit 20.

The second circuit component 84 is disposed on the first principal surface 121 of the module laminate 12. In the example of FIG. 10, the first IC chip 81A and the second circuit component 84 are adjacent to each other on the first principal surface 121 of the module laminate 12. Similarly to the second circuit component 84 according to Embodiment 1, the second circuit component 84 includes, for example, the capacitor C21 of the switched-capacitor circuit 20.

The plurality of external connection terminals 18 is disposed on the second principal surface 122 of the module laminate 12.

### (2) Radio Frequency Module

In an exemplary aspect, as illustrated in FIG. 10, the radio frequency module 300d according to Reference Example 1 includes the module laminate 13, and the plurality of circuit components 9 disposed on the module laminate 13. The plurality of circuit components 9 includes the first circuit component 91, a second circuit component 92A, the third circuit component 93, and the fourth circuit component 94.

The first circuit component 91 is disposed in the first principal surface 131 of the module laminate 13. Similarly to the first circuit component 91 according to Embodiment 1, the first circuit component 91 includes the power amplifier 2.

The second circuit component 92A is disposed on the second principal surface 132 of the module laminate 13. The second circuit component 92A includes a low noise amplifier (not illustrated) and the control circuit 4. That is, the tracker module 100d according to Reference Example 1 does not include the control circuit 4.

The third circuit component 93 is disposed on the first principal surface 131 of the module laminate 13. In the example of FIG. 10, the first circuit component 91 and the third circuit component 93 are adjacent to each other on the first principal surface 131 of the module laminate 13. Similarly to the third circuit component 93 according to Embodiment 1, the third circuit component 93 includes, for example, a capacitor that forms a part of the input matching circuit.

The fourth circuit component 94 is disposed on the second principal surface 132 of the module laminate 13. In the example of FIG. 10, the second circuit component 92A and the fourth circuit component 94 are adjacent to each other on the second principal surface 132 of the module laminate 13. Similarly to the fourth circuit component 94 according to Embodiment 1, the fourth circuit component 94 includes, a capacitor that forms a part of the output matching circuit.

### (3) Structure of Radio Frequency System

In an exemplary aspect, a description of the structure of the radio frequency system 200d according to Reference Example 1 can be provided with reference to FIG. 10.

As illustrated in FIG. 10, the radio frequency system 200d according to Reference Example 1 includes the motherboard 11, the tracker module 100d, the radio frequency module 300d, the power inductor L71, and the RFIC 51.

As illustrated in FIG. 10, the tracker module 100d, the radio frequency module 300d, the power inductor L71, and the RFIC 51 are disposed on the first principal surface 101 of the motherboard 11. The tracker module 100d and the radio frequency module 300d are positioned side-by-side in the second direction D2 orthogonal to the first direction D1 that is the thickness direction of the motherboard 11. In the second direction D2, the power inductor L71 is located between the tracker module 100d and the radio frequency module 300d. In the second direction D2, the RFIC 51 is located on the opposite side of the tracker module 100d from the power inductor L71. That is, on the first principal surface 101 of the motherboard 11, the tracker module 100d, the radio frequency module 300d, the power inductor L71, and the RFIC 51 are positioned side-by-side, from one end side (e.g., left side of FIG. 10) to another end side (e.g., right side of FIG. 10) in the second direction D2, in the order of the RFIC 51, the tracker module 100d, the power inductor L71, and the radio frequency module 300d.

### (4) Structure of Communication Device

The communication device 7d includes the radio frequency system 200d, a signal processing circuit, such as the signal processing circuit 5 shown in FIG. 2, disposed on the motherboard 11 of the radio frequency system 200d, and an antenna, such as the antenna 6 shown in FIG. 2. Note that the communication device 7d may include a second motherboard where the radio frequency system 200d and the signal processing circuit 5 are disposed, in addition to a first motherboard that is the motherboard 11 of the radio frequency system 200d.

### (5) Effects

In the disclosure according to Reference Example 1, as the signal generation unit 70 is included in the first IC chip 81A, it is possible to reduce the size of the entire transmission system including the power amplifier 2, as compared with a case in which the signal generation unit 70 is not included in the first IC chip 81A.

### Reference Example 2

A description of a tracker module 100e according to Reference Example 2 can be provided with reference to FIG. 11. The same reference numerals can be assigned to components of the tracker module 100e according to Reference Example 2 similar to those of the tracker module 100 (See FIG. 1) according to Embodiment 1, and a description thereof will be omitted.

### (1) Structure of Tracker Module

A description of the tracker module 100e according to Reference Example 2 can be provided with reference to FIG. 11.

As illustrated in FIG. 11, the tracker module 100e according to Reference Example 2 includes the module laminate 12 and the plurality of circuit components 8 disposed on the module laminate 12. The plurality of circuit components 8 includes the first IC chip 81A, the first circuit component 83, and the second circuit component 84. In addition, the tracker module 100e further includes the plurality of external connection terminals 18, the first resin layer 14, the shield electrode layer 16, and the second resin layer 24.

In an exemplary aspect, the first IC chip 81A is disposed on the second principal surface 122 of the module laminate 12. The first IC chip 81A includes the plurality of switches S11 to S14, S21 to S24, S31 to S34, and S41 to S44 included in the switched-capacitor circuit 20, the plurality of switches S51 to S54 of the supply modulator 30, and the signal generation unit 70.

The first circuit component 83 is disposed on the first principal surface 121 of the module laminate 12. Similarly to the first circuit component 83 according to Embodiment 1, the first circuit component 83 includes, for example, the capacitor C23 of the switched-capacitor circuit 20.

The second circuit component 84 is disposed on the first principal surface 121 of the module laminate 12. In the example of FIG. 11, the first circuit component 83 and the second circuit component 84 are adjacent to each other on the first principal surface 121 of the module laminate 12. Similarly to the second circuit component 84 according to Embodiment 1, the second circuit component 84 includes, for example, the capacitor C21 of the switched-capacitor circuit 20.

The plurality of external connection terminals 18 is disposed on the second principal surface 122 of the module laminate 12. Each of the plurality of external connection terminals 18 is connected to the module laminate 12 with the corresponding connection terminal 25 of the plurality of connection terminals 25 interposed therebetween.

As such, the tracker module 100e according to Reference Example 2 may not include the control circuit 4.

### (2) Effects

In the disclosure according to Reference Example 2, as the signal generation unit 70 is included in the first IC chip 81A, it is possible to reduce the size of the entire transmission system including the power amplifier 2, as compared with a case in which the signal generation unit 70 is not included in the first IC chip 81A.

### Aspects

Exemplary aspects are disclosed in the disclosure as follows.

A tracker module (e.g., the tracker module 100, 100a, 100b, or 100c) according to a first aspect includes a module laminate (e.g., the module laminate 12), a first IC chip (e.g., first IC chip 81 or 81A), and a second IC chip (e.g., second IC chip 82 or 82A). The first IC chip (e.g., the first IC chip 81 or 81A) is disposed on the module laminate (e.g., the module laminate 12). The second IC chip (e.g., the second IC chip 82 or 82A) controls a power amplifier (e.g., the power amplifier 2). The first IC chip (e.g., the first IC chip 81 or 81A) includes at least one switch (e.g., switches S11 to S14, S21 to S24, S31 to S34, and S41 to S44) included in a switched-capacitor circuit (e.g., the switched-capacitor circuit 20) and at least one switch (e.g., switches S51 to S54) included in a supply modulator (e.g., the supply modulator 30). The switched-capacitor circuit (e.g., switched-capacitor circuit 20) is configured to generate a plurality of discrete voltages based on an input voltage, and the supply modulator (e.g., the supply modulator 30) is configured to selectively output at least one of the plurality of discrete voltages to the power amplifier (e.g., the power amplifier 2). The second IC chip (e.g., the second IC chip 82 or 82A) is disposed on the module laminate 12 where the first IC chip (e.g., the first IC chip 81 or 81A) is disposed.

According to this aspect, as the second IC chip (e.g., the second IC chip 82 or 82A) that controls the power amplifier (e.g., the power amplifier 2) is disposed on the module laminate (e.g., module laminate 12), it is possible to reduce the size of the entire transmission system including the power amplifier (e.g., power amplifier 2), as compared with a case in which the second IC chip (e.g., the second IC chip 82 or 82A) is not disposed on the module laminate (e.g., the module laminate 12).

A tracker module (e.g., the tracker module 100, 100a, 100b, or 100c) according to a second aspect includes a second module laminate (e.g., second module laminate 12), a first IC chip (e.g., the first IC chip 81 or 81A), and a second IC chip (e.g., second IC chip 82 or 82A). The second module laminate (e.g., second module laminate 12) is a separate body from a first module laminate (e.g., first module laminate 13) where a power amplifier (e.g., power amplifier 2) is disposed. The first IC chip (e.g., first IC chip 81 or 81A) is disposed on a module laminate (e.g., module laminate 12) that is the second module laminate (e.g., second module laminate 12). The second IC chip (e.g., second IC chip 82 or 82A) controls the power amplifier (e.g., the power amplifier 2). The first IC chip (e.g., the first IC chip 81 or 81A) includes at least one switch (e.g., switches S11 to S14, S21 to S24, S31 to S34, and S41 to S44) included in a switched-capacitor circuit (e.g., switched-capacitor circuit 20) and at least one switch (e.g., switches S51 to S54) included in a supply modulator (e.g., supply modulator 30), the switched-capacitor circuit (e.g., switched-capacitor circuit 20) being configured to generate a plurality of discrete voltages based on an input voltage, and the supply modulator (e.g., supply modulator 30) being configured to selectively output at least one of the plurality of discrete voltages to the power amplifier (e.g., power amplifier 2). The second IC chip (e.g., second IC chip 82 or 82A) is disposed on the module laminate (e.g., module laminate 12) where the first IC chip (e.g., first IC chip 81 or 81A) is disposed.

According to this aspect, as the second IC chip (e.g., second IC chip 82 or 82A) that controls the power amplifier (e.g., power amplifier 2) is disposed on the module laminate (e.g., module laminate 12), it is possible to reduce the size of the entire transmission system including the power amplifier (e.g., power amplifier 2), as compared with a case in which the second IC chip (e.g., second IC chip 82 or 82A) is not disposed on the module laminate (e.g., module laminate 12).

In a tracker module (e.g., tracker module 100a or 100b) according to a third aspect, in the first or second aspect, the module laminate (e.g., module laminate 12) has a first principal surface (e.g., first principal surface 121) and a second principal surface (e.g., second principal surface 122) that face each other. The tracker module (e.g., tracker module 100a or 100b) further includes an external connection terminal (e.g., external connection terminal 18). The external connection terminal (e.g., external connection terminal 18) is disposed on the second principal surface (e.g., second principal surface 122) of the module laminate (e.g., module laminate 12). The first IC chip (e.g., first IC chip 81A) is disposed on the second principal surface (e.g., second principal surface 122) of the module laminate (e.g., module laminate 12). The second IC chip (e.g., second IC chip 82A) is disposed on the first principal surface (e.g., first principal surface 121) of the module laminate (e.g., module laminate 12).

According to this aspect, it is possible to radiate the heat generated in the first IC chip (e.g., first IC chip 81A) to the motherboard (e.g., motherboard 11).

In a tracker module (e.g., tracker module 100c) according to a fourth exemplary aspect, in the first or second aspect, the module laminate (e.g., module laminate 12) has a first principal surface (e.g., first principal surface 121) and a second principal surface (e.g., second principal surface 122) that face each other. The tracker module (e.g., tracker module 100c) further includes an external connection terminal (e.g., external connection terminal 18). The external connection terminal (e.g., external connection terminal 18) is disposed on the second principal surface (e.g., second principal surface 122) of the module laminate (e.g., module laminate 12). The first IC chip (e.g., first IC chip 81A) is disposed on the first principal surface (e.g., first principal surface 121) of the module laminate (e.g., module laminate 12). The second IC chip (e.g., second IC chip 82A) is disposed on the second principal surface (e.g., second principal surface 122) of the module laminate (e.g., module laminate 12).

According to this aspect, for example, if a first circuit component (e.g., first circuit component 83) including a capacitor (e.g., C23) of a switched-capacitor circuit (e.g., switched-capacitor circuit 20) is disposed on the first principal surface (e.g., first principal surface 121) of the module laminate (e.g., module laminate 12), it is possible to shorten the distance between the first IC chip (e.g., first IC chip 81A) and the first circuit component (e.g., first circuit component 83).

In a tracker module (e.g., tracker module 100) according to a fifth exemplary aspect, in the first or second aspect, the module laminate (e.g., module laminate 12) has a first principal surface (e.g., first principal surface 121) and a second principal surface (e.g., second principal surface 122) that face each other. The first IC chip (e.g., first IC chip 81) and the second IC chip (e.g., second IC chip 82) are disposed on the first principal surface (e.g., first principal surface 121) or the second principal surface (e.g., second principal surface 122) of the module laminate (e.g., module laminate 12).

According to this aspect, it is possible to make the tracker module (e.g., tracker module 100) thinner than that in a case in which the first IC chip (e.g., first IC chip 81) and the second IC chip (e.g., second IC chip 82) are disposed on separate principal surfaces.

In a tracker module (e.g., tracker module 100) according to a sixth exemplary aspect, in the fifth aspect, the first IC chip (e.g., first IC chip 81) and the second IC chip (e.g., second IC chip 82) are integrated.

According to this aspect, it is possible to make the surface area of the module laminate (e.g., module laminate 12) smaller than that in a case in which the first IC chip (e.g., first IC chip 81) and the second IC chip (e.g., second IC chip 82) are separate bodies.

A tracker module (e.g., tracker module 100, 100a, 100b, or 100c) according to a seventh aspect further includes a signal generation unit (e.g., signal generation unit 70) in any one of the first to sixth aspects. The signal generation unit (e.g., signal generation unit 70) generates a control signal for controlling the supply modulator (e.g., supply modulator 30) based on an envelope of a radio frequency signal. The signal generation unit (e.g., signal generation unit 70) is disposed on the module laminate (e.g., module laminate 12).

According to this aspect, it is possible to reduce the size of the entire transmission system including the power amplifier (e.g., power amplifier 2), as compared with a case in which the signal generation unit (e.g., signal generation unit 70) is not disposed on the module laminate (e.g., module laminate 12).

In a tracker module (e.g., tracker module 100, 100a, 100b, or 100c) according to an eighth aspect, in the seventh aspect, the signal generation unit (e.g., signal generation unit 70) is included in the first IC chip (e.g., first IC chip 81 or 81A).

According to this aspect, it is possible to reduce the size of the entire transmission system including the power amplifier (e.g., power amplifier 2), as compared with a case in which the signal generation unit (e.g., signal generation unit 70) is not included in the first IC chip (e.g., first IC chip 81 or 81A).

A tracker module (e.g., tracker module 100, 100a, 100b, or 100c) according to a ninth exemplary aspect further includes a control terminal (e.g., control terminal 184) in any one of the first to eighth aspects. The control terminal (e.g., control terminal 184) is connected to the second IC chip (e.g., second IC chip 82 or 82A) and outputs a control signal for controlling the power amplifier (e.g., power amplifier 2).

According to this aspect, it is possible to output a control signal for the power amplifier (e.g., power amplifier 2).

In a tracker module (e.g., tracker module 100, 100a, 100b, or 100c) according to a tenth exemplary aspect, in the ninth aspect, the control terminal (e.g., control terminal 184) is disposed on the module laminate (e.g., module laminate 12) so as to overlap the second IC chip (e.g., second IC chip 82 or 82A) in a thickness direction (e.g., D1) of the module laminate (e.g., module laminate 12).

According to this aspect, it is possible to shorten the wiring length between the second IC chip (e.g., second IC chip 82 or 82A) and the control terminal (e.g., control terminal 184).

A radio frequency system (e.g., radio frequency system 200a) according to an eleventh exemplary aspect includes the tracker module (e.g., tracker module 100a) according to the first aspect and the power amplifier (e.g., power amplifier 2). The power amplifier (e.g., power amplifier 2) is disposed on the module laminate (e.g., module laminate 12).

According to this aspect, it is possible to reduce the size of the entire transmission system including the power amplifier (e.g., power amplifier 2).

A communication device (e.g., communication device 7a) according to a twelfth exemplary aspect includes the radio frequency system (e.g., radio frequency system 200a) according to the eleventh aspect and a signal processing circuit (e.g., signal processing circuit 5). The signal processing circuit (e.g., signal processing circuit 5) is connected to the radio frequency system (e.g., radio frequency system 200a).

According to this aspect, it is possible to reduce the size of the entire transmission system including the power amplifier (e.g., power amplifier 2).

What is claimed:

1. A tracker module comprising:
a module laminate;
a first IC chip disposed on the module laminate; and
a second IC chip configured to control a power amplifier,
wherein the first IC chip includes:
at least one switch included in a switched-capacitor circuit that is configured to generate a plurality of discrete voltages based on an input voltage; and
at least one switch included in a supply modulator that is configured to selectively output at least one of the plurality of discrete voltages to the power amplifier, and
wherein the second IC chip is disposed on the module laminate and coupled to the first IC chip.

2. The tracker module according to claim 1, further comprising another module laminate that is separated from the module laminate, and the power amplifier is disposed on the other module laminate.

3. The tracker module according to claim 1, wherein:
the module laminate has a first principal surface and a second principal surface that is opposite to the first principal surface,
the tracker module further comprises an external connection terminal disposed on the second principal surface of the module laminate,
the first IC chip is disposed on the second principal surface of the module laminate, and
the second IC chip is disposed on the first principal surface of the module laminate.

4. The tracker module according to claim 1, wherein:
the module laminate has a first principal surface and a second principal surface that is opposite to the first principal surface,
the tracker module further comprises an external connection terminal disposed on the second principal surface of the module laminate,
the first IC chip is disposed on the first principal surface of the module laminate, and
the second IC chip is disposed on the second principal surface of the module laminate.

5. The tracker module according to claim 1, wherein:
the module laminate has a first principal surface and a second principal surface that is opposite to the first principal surface, and
the first IC chip and the second IC chip are disposed on one of the first principal surface and the second principal surface of the module laminate.

6. The tracker module according to claim 5, wherein each of the first IC chip and the second IC chip is a respective integrated circuit.

7. The tracker module according to claim 1, further comprising a signal generation unit that is configured to generate a control signal for controlling the supply modulator based on an envelope of a radio frequency signal.

8. The tracker module according to claim 7, wherein the signal generation unit is included in the first IC chip.

9. The tracker module according to claim 1, further comprising a control terminal that is coupled between the second IC chip and the power amplifier, and is configured to output a control signal generated from the second IC chip to the power amplifier for controlling the power amplifier.

10. The tracker module according to claim 9, wherein the control terminal is disposed on the module laminate and overlaps the second IC chip in a thickness direction of the module laminate.

11. The tracker module according to claim 1, further comprising a first circuit component that is disposed on the module laminate, coupled to the first IC chip, and includes at least one capacitor of the switched-capacitor circuit.

12. The tracker module according to claim 11, further comprising a second circuit component that is disposed on the module laminate and includes at least one capacitor of the switched-capacitor circuit.

13. The tracker module according to claim 12, further comprising a third circuit component that is disposed on the module laminate and includes the power amplifier.

14. A radio frequency system comprising:
a tracker module; and
a power amplifier that is coupled to the tracker module and configured to amplify and output a radio frequency transmission signal that is outputted from a signal processing circuit,
wherein the power amplifier is disposed on a module laminate,
wherein the tracker module includes:
a first IC chip disposed on the module laminate; and
a second IC chip configured to control the power amplifier,
wherein the first IC chip includes:
at least one switch included in a switched-capacitor circuit that is configured to generate a plurality of discrete voltages based on an input voltage; and
at least one switch included in a supply modulator that is configured to selectively output at least one of the plurality of discrete voltages to the power amplifier, and
wherein the second IC chip is disposed on the module laminate and coupled to the first IC chip.

15. The radio frequency system according to claim 14, further comprising another module laminate that is separated from the module laminate, and the power amplifier is disposed on the other module laminate.

16. The radio frequency system according to claim 14, wherein:
the module laminate has a first principal surface and a second principal surface that is opposite to the first principal surface,
the tracker module further comprises an external connection terminal disposed on the second principal surface of the module laminate,
the first IC chip is disposed on the second principal surface of the module laminate, and
the second IC chip is disposed on the first principal surface of the module laminate.

17. The radio frequency system according to claim 14, wherein:
the module laminate has a first principal surface and a second principal surface that is opposite to the first principal surface,
the tracker module further comprises an external connection terminal disposed on the second principal surface of the module laminate,
the first IC chip is disposed on the first principal surface of the module laminate, and
the second IC chip is disposed on the second principal surface of the module laminate.

18. The radio frequency system according to claim 14, wherein:
the module laminate has a first principal surface and a second principal surface that is opposite to the first principal surface, and
the first IC chip and the second IC chip are disposed on one of the first principal surface and the second principal surface of the module laminate.

19. The radio frequency system according to claim 14, further comprising a signal generation unit that is configured to generate a control signal for controlling the supply modulator based on an envelope of a radio frequency signal.

20. A communication device comprising:
a radio frequency system; and
a signal processing circuit coupled to the radio frequency system,
wherein the radio frequency system comprises:
a tracker module; and
a power amplifier that is coupled to the tracker module and is configured to amplify and output a radio frequency transmission signal that is outputted from the signal processing circuit,
wherein the power amplifier is disposed on a module laminate,
wherein the tracker module further includes:
a first IC chip disposed on the module laminate; and
a second IC chip configured to control the power amplifier,
wherein the first IC chip includes:
at least one switch included in a switched-capacitor circuit that is configured to generate a plurality of discrete voltages based on an input voltage; and
at least one switch included in a supply modulator that is configured to selectively output at least one of the plurality of discrete voltages to the power amplifier, and
wherein the second IC chip is disposed on the module laminate and coupled to the first IC chip.
